(19) United States
(12) Patent Application Publication
(10) Pub. No.: US 2026/0367117 A1
(43) Pub. Date: Nov. 19, 2026

(54) METHODS AND SYSTEMS FOR STABILIZING A PARTICLE BEAM

(71) Applicant: Tau Systems Inc., Austin, TX (US)

(72) Inventor: Stephen V. MILTON, Santa Fe, NM (US)

(21) Appl. No.: 19/731,549

(22) Filed: Jul. 6, 2026

Related U.S. Application Data
(63) Continuation of application No. PCT/US2026/016107, filed on Feb. 20, 2026.
(60) Provisional application No. 63/761,387, filed on Feb. 21, 2025.

(51) Int. Cl. G01R 19/00; G01R 31/28; H05H 15/00

(52) U.S. Cl. CPC G01R 19/0061; G01R 31/2881; H05H 15/00

(57) ABSTRACT

Disclosed herein are precision electron-based test systems. The test systems comprise a particle beam; a first aperture on an axis of propagation of the particle beam, wherein the first aperture forms a virtual source configured to sample a portion of the particle beam; and a telescopic subsystem for the portion of the particle beam from the virtual source, wherein the telescopic subsystem is configured to image the portion of the particle beam onto a sample area.

### CROSS-REFERENCE

This application is a continuation of International Application No. PCT/US2026/016107, filed Feb. 20, 2026, which claims the benefit of U.S. Provisional Application Ser. No. 63/761,387, filed on Feb. 21, 2025, which is incorporated by reference herein for all purposes.

### BACKGROUND

As electronics become more sophisticated, they become susceptible to radiation events such as those generated by the natural cosmic radiation. To study this impact and to improve the performance of the electronics in a radiation environment, such as that experienced in space, controlled single event effect radiation testing is done in the laboratory. Single-event testing of electronics is often done with heavy ion beams, pulsed laser systems, or high-energy pulsed x-rays (often exceeding 80 keV).

Facilities providing heavy ions are large, and none have been built specifically for single-event effect testing of electronics. Similarly, facilities capable of providing x-ray pulses suitable for use in single-event testing are large and none have been built specifically for such work. High-energy electrons can be used as a surrogate to heavy ions.

### SUMMARY

Current single-event effect testing employs the use of heavy ion beams. As an alternative, high-energy electrons, exceeding 80 keV, may be generated and used instead. If these high-energy electrons are delivered as a transversely and longitudinally small charge packet, these electrons can mimic the impact of a heavy ion on electronics making these high-energy electron packets an effective surrogate to the use of heavy ion beams in single event effect testing. If these electron bunches are of sufficient energy they can also travel through thick material without spreading significantly in the transverse direction. The devices, methods, and systems discussed herein address these and other benefits of the use of precision electron-based single-event effect test systems.

In accordance with the purposes of the disclosed devices, methods, and systems as embodied and broadly described herein, the disclosed subject matter relates to precision electron-based single-event effect test systems and methods of use thereof and methods of beam stabilization. Applicant has recognized that existing heavy ion facilities used for single event testing are not sufficient for the electronics testing community and that more capacity may be achieved. The applicant also recognizes that electron bunches properly generated and precisely delivered can act as a surrogate for heavy ions in single-event effect testing. Achieving that precise delivery, stability, and control allows the use of electrons for single-event testing and other research opportunities.

In an aspect, the present disclosure provides a system. The system comprises: a source of a particle beam; a first aperture on an axis of propagation of the particle beam, wherein the first aperture forms a virtual source comprising a sample of the particle beam; and a telescopic subsystem for the sample of the particle beam, wherein the telescopic subsystem is configured to image the sample of the particle beam onto a sample area, wherein, at the sample area, the sample of the particle beam comprises a more stable centroid energy than the source of the particle beam.

In an aspect, the present disclosure provides a system. The system comprises: a source of a particle beam; a first aperture on an axis of propagation of the particle beam, wherein the first aperture forms a virtual source comprising a sample of the particle beam; and a telescopic subsystem for the sample of the particle beam, wherein the telescopic subsystem is configured to image the sample of the particle beam onto a sample area, wherein, at the sample area, the sample of the particle beam comprises a more stable pointing stability than the source of the particle beam.

In an aspect, the present disclosure provides a system. The system comprises: a source of a particle beam with an energy of at least 4 megaelectron Volts (MeV); a first aperture on an axis of propagation of the particle beam, wherein the first aperture forms a virtual source comprising a sample of the particle beam; and a telescopic subsystem for the sample of the particle beam, wherein the telescopic subsystem is configured to image the sample of the particle beam onto a sample area, wherein, at the sample area, at least one property of the sample of the particle beam is more stable than the source of the particle beam.

In an aspect, the present disclosure provides a system for single event effect testing. The system comprises: a source of a particle beam; a first aperture on an axis of propagation of the particle beam, wherein the first aperture forms a virtual source comprising a sample of the particle beam; and a telescopic subsystem for the sample of the particle beam, wherein the telescopic subsystem is configured to image the portion of the particle beam onto a sample area, wherein, at the sample area, at least one property of the sample of the particle beam is more stable than the source of the particle beam, and wherein the sample area comprises a single event effect testing sample.

In some embodiments, at the sample area, the sample of the particle beam comprises a more stable beam energy spread than the source of the particle beam. In some embodiments, at the sample area, the sample of the particle beam comprises a more stable particle beam location than the source of the particle beam.

In some embodiments, the system does not comprise an aperture other than the first aperture. In some embodiments, the system further comprises a second aperture. In some embodiments, the second aperture is positioned before the first aperture along the axis of propagation. In some embodiments, the second aperture is positioned on a reflective surface. In some embodiments, the reflective surface is a mirror.

In some embodiments, the particle beam is an electron beam. In some embodiments, the energy of the particle beam is greater than 5 MeV. In some embodiments, the particle beam energy is greater than 50 MeV. In some embodiments, the particle beam energy is greater than 100 MeV. In some embodiments, the particle beam before the first aperture comprises a beam jitter characterized by a deviation in angle of greater than 0.1 milliradian. In some embodiments, the particle beam before the first aperture comprises a beam jitter characterized by an offset of greater than 0.1 millimeter.

In some embodiments, the system further comprises a particle beam source configured to generate the particle beam. In some embodiments, the particle beam source is a wakefield accelerator system. In some embodiments, the wakefield accelerator system is driven by a laser. In some embodiments, the wakefield accelerator system is driven by a particle beam. In some embodiments, the particle beam source is a radiofrequency accelerator.

In some embodiments, the first aperture is configured to limit a transverse pointing error and a beam size to form the portion of the particle beam. In some embodiments, the first aperture is configured to select a centroid energy and an energy range of the particle beam to form the portion of the particle beam. In some embodiments, the first aperture is configured to select a centroid energy range from the particle beam with an energy greater than 4 MeV to form the portion of the particle beam. In some embodiments, the centroid energy is greater than 50 MeV. In some embodiments, the centroid energy is greater than 100 MeV.

In some embodiments, the first aperture defines a virtual source point of the portion of the beam. In some embodiments, the first aperture is a pinhole. In some embodiments, the first aperture is a slit. In some embodiments, the first aperture is a combination of slits. In some embodiments, the first aperture is fixed. In some embodiments, the first aperture is adjustable along the axis of propagation. In some embodiments, the first aperture is adjustable along one or more axes not colinear with the axis of propagation. In some embodiments, the jitter of the portion of the particle beam following the first aperture is less than the particle beam before the first aperture. In some embodiments, the virtual source energy is controlled by the location of the first aperture. In some embodiments, the portion of the particle beam comprises an energy spread around the centroid energy of the particle beam from the virtual source of less than 10% of the centroid energy. In some embodiments, the energy spread around the centroid energy is less than 1% of the centroid energy. In some embodiments, the energy spread around the centroid energy is less than 0.1% of the centroid energy.

In some embodiments, the telescopic subsystem is configured to perform a variable transverse demagnification from the virtual source to the sample area. In some embodiments, the telescopic subsystem is tunable. In some embodiments, the telescopic subsystem further comprises two or more magnetic quadrupoles. In some embodiments, the two or more magnetic quadrupoles are adjustable. In some embodiments, the two or more magnetic quadrupoles are adjustable along the axis of propagation. In some embodiments, the telescopic subsystem comprises one or more magnetic solenoids. In some embodiments, the one or more magnetic solenoids are adjustable. In some embodiments, the one or more magnetic solenoids are adjustable along the axis of propagation. In some embodiments, the telescopic subsystem comprises a DC or a pulsed magnetic field. In some embodiments, the telescopic subsystem possesses a demagnification ratio of greater than 1:1. In some embodiments, the telescopic subsystem possesses a demagnification ratio of greater than 5:1. In some embodiments, the telescopic subsystem possesses a demagnification ratio of greater than 50:1. In some embodiments, the telescopic subsystem possesses a demagnification ratio of greater than 100:1.

In some embodiments, the system further comprises a device under test, wherein the sample area comprises the device under test. In some embodiments, the system further comprises a sample chamber, wherein the sample chamber comprises the sample area. In some embodiments, the demagnified image of the virtual source resides in the sample chamber. In some embodiments, the demagnified image of the virtual source in the sample chamber has a transverse size of <10 micron. In some embodiments, the demagnified image of the virtual source in the sample chamber has a transverse size of <1 micron. In some embodiments, the longitudinal duration of the bunch at the sample chamber is <1 picosecond. In some embodiments, the sample chamber further comprises a particle beam detector. In some embodiments, the sample chamber further comprises a charged particle catch. In some embodiments, the charged particle catch is a charge detector. In some embodiments, the charge detector is calibrated.

In some embodiments, the system further comprises a first and second dispersive element along the axis of propagation, wherein the first dispersive element is before the first aperture, and wherein the second dispersive element is after the first aperture. In some embodiments, the first dispersive element comprises a first dipole and a second dipole, and wherein the second dispersive element comprises a third dipole and a fourth dipole. In some embodiments, the dispersive element is configured to further define the beam energy and energy spread. In some embodiments, the dispersive element is configured to reduce the particle beam energy deviation as compared to the particle beam energy deviation upon introduction. In some embodiments, the dispersive element is configured to reduce the particle beam energy variation to less than 1%. In some embodiments, the dispersive element is configured to reduce the particle beam energy variation to less than 0.1%.

In some embodiments, the system further comprises a beam stop positioned along the axis of propagation after the sample area. In some embodiments, the system is further configured to stabilize the energy variations of the output beam. In some embodiments, the system is further configured to stabilize the charge fluctuation of the output beam. In some embodiments, the portion of the electron beam is an electron bunch with a charge from 100 femtocoulomb to 1 attocoulomb.

In some embodiments, the system is a single event effect testing system. In some embodiments, the system is a single electron event testing system.

In an aspect, the present disclosure provides a method for stabilizing a particle beam. In some embodiments, the method comprises: (a) providing a particle beam; (b) passing the particle beam through a first aperture to form a virtual source comprising a sample of the particle beam; (c) demagnifying the sample of the particle beam with a telescopic subsystem; and (d) directing the portion of the particle beam toward a sample area, wherein a pointing stability of the portion of the particle beam on the sample area is improved relative to the pointing stability of the particle beam based at least in part on the first aperture.

In some embodiments, the sample of the particle beam at (b) is formed by clipping an edge of the particle beam with the first aperture.

In some embodiments, at (b), the method further comprises: stabilizing a transverse beam jitter using the first aperture; forming the virtual source of the stabilized portion of the particle beam using a second aperture; stabilizing a beam energy and an energy spread of the portion of the beam using the second aperture; and imaging the virtual source onto a device under test such that a transverse spot size is smaller than 10 μm.

In some embodiments, the particle beam in (a) has an energy greater than 4 MeV. In some embodiments, the particle beam in (a) has an energy greater than 5 MeV. In some embodiments, the particle beam energy is greater than 100 MeV. In some embodiments, the particle beam energy is greater than 1000 MeV. In some embodiments, the particle beam in (a) comprises a beam jitter characterized by a deviation in angle of greater than 0.1 milliradian. In some embodiments, the particle beam in (a) is from a particle beam source, wherein the particle beam source is a wakefield accelerator system.

In some embodiments, the portion of the particle beam sampled in (b) is a central portion. In some embodiments, the method at (b) further comprises sampling a central portion of the particle beam with an energy greater than 4 MeV. In some embodiments, the method at (b) further comprises sampling a central portion of the particle beam with an energy greater than 50 MeV. In some embodiments, a position of the first aperture in (b) may be adjusted, altering the sampled energy.

In some embodiments, the method at (b) further comprises clipping the edges of the particle beam, wherein the clipping reduces the variation in the centroid energy of the particle beam from the virtual source to less than 0.2%.

In some embodiments, the pointing stability is improved by decreasing a particle beam jitter by at least 60% relative to the stability of the provided particle beam. In some embodiments, the pointing stability is improved by decreasing a particle beam jitter by at least 80% relative to the stability of the provided particle beam. In some embodiments, the pointing stability is improved by decreasing a particle beam jitter to no greater than 0.5 milliradian.

In some embodiments, the virtual source is imaged to a less than 10 micron spot on the device under test.

In an aspect, the present disclosure provides a method for stabilizing a particle beam. In some embodiments, the method comprises: (a) providing a particle beam; (b) sampling a portion of the particle beam by passing the particle beam through a first aperture to form a virtual source comprising a sample of the particle beam; (c) demagnifying the portion of the particle beam from the virtual source with a telescopic subsystem; and (d) directing the portion of the particle beam toward a sample area, wherein an energy spread of the portion the particle beam on the sample area is improved relative to the energy spread of the particle beam.

In some embodiments, the sample of the particle beam at (b) is formed by clipping an edge of the particle beam with the first aperture.

In some embodiments, the particle beam in (a) has an energy spread of at least ±10 MeV. In some embodiments, the particle beam in (a) has an energy greater than 4 MeV. In some embodiments, the particle beam in (a) has an energy greater than 50 MeV. In some embodiments, the particle beam in (a) is from a particle beam source, wherein the particle beam source is a wakefield accelerator system.

In some embodiments, the portion of the particle beam sampled in (b) is a central portion. In some embodiments, the method at (b) further comprises sampling a central portion of the particle beam with an energy greater than 4 MeV. In some embodiments, the method at (b) further comprises sampling a central portion of the particle beam with an energy greater than 50 MeV.

In some embodiments, a cross sectional area of the first aperture in (b) may be adjusted, wherein the energy spread is reduced. In some embodiments, enlarging the cross sectional area of the first aperture increases the energy spread. In some embodiments, shrinking the cross sectional area of the first aperture decreases the energy spread.

In some embodiments, the energy spread of the portion of the particle beam is reduced to <±5 MeV. In some embodiments, the energy spread of the portion of the particle beam is reduced to <±1 MeV. In some embodiments, the virtual source is imaged to a less than 10 micron spot on the device under test.

In an aspect, the present disclosure provides a method for stabilizing a particle beam. In some embodiments, the method comprises: (a) providing a particle beam; (b) sampling a portion of the particle beam by passing the particle beam through a first aperture to form a virtual source comprising a sample of the particle beam; (c) demagnifying the portion of the particle beam from the virtual source with a telescopic subsystem; and (d) directing the portion of the particle beam toward a sample area, wherein a charge fluctuation of the portion of the particle beam on the sample area is improved relative to the charge fluctuation of the particle beam.

In some embodiments, the sample of the particle beam at (b) is formed by clipping an edge of the particle beam with the first aperture.

In some embodiments, the particle beam in (a) has an energy greater than 4 MeV. In some embodiments, the particle beam in (a) has an energy greater than 50 MeV. In some embodiments, the particle beam in (a) is from a particle beam source, wherein the particle beam source is a wakefield accelerator system. In some embodiments, the charge distribution of the particle beam in (a) is non-uniform. In some embodiments, the central portion of the particle beam in (a) possesses a smaller charge density fluctuation than a charge density fluctuation in the outer regions of the particle beam.

In some embodiments, a cross sectional area of the first aperture in (b) may be adjusted, wherein the charge density fluctuation is altered. In some embodiments, enlarging the cross sectional area of the first aperture increases the charge density fluctuation across the portion of the particle beam. In some embodiments, shrinking the cross sectional area of the first aperture decreases the charge fluctuation across the portion of the particle beam. In some embodiments, the charge fluctuation across the portion of the particle beam is reduced by greater than 50% relative to the charge fluctuation of the particle beam.

In an aspect, the present disclosure provides a system. The system of beam stabilization comprises a particle beam; a first aperture on an axis of propagation of the particle beam, wherein the first aperture forms a virtual source configured to sample a portion of the particle beam; and a telescopic subsystem for the portion of the particle beam from the virtual source, wherein the telescopic subsystem is configured to image the portion of the particle beam onto a sample area; wherein the first aperture is configured to stabilize the particle beam centroid energy.

In an aspect, the present disclosure provides a system. The system for beam stabilization comprises a particle beam; a first aperture on an axis of propagation of the particle beam, wherein the first aperture forms a virtual source configured to sample a portion of the particle beam; and a telescopic subsystem for the portion of the particle beam from the virtual source, wherein the telescopic subsystem is configured to image the portion of the particle beam onto a sample area; wherein the first aperture is configured to stabilize at least a pointing stability of the portion of the particle beam on the sample area.

In some embodiments, the first aperture is configured to stabilize the particle beam energy spread. In some embodiments, the first aperture is configured to stabilize the particle beam location. In some embodiments, the system does not comprise an aperture other than the first aperture. In some embodiments, the system further comprises a second aperture. In some embodiments, the second aperture is positioned before the first aperture along the axis of propagation. In some embodiments, the second aperture is positioned on a reflective surface. In some embodiments, the reflective surface is a mirror.

In some embodiments, the particle beam is an electron beam. In some embodiments, the energy of the particle beam is greater than 5 MeV. In some embodiments, the particle beam energy is greater than 50 MeV. In some embodiments, the particle beam energy is greater than 100 MeV. In some embodiments, the particle beam before the first aperture comprises a beam jitter characterized by a deviation in angle of greater than 0.1 milliradian. In some embodiments, the particle beam before the first aperture comprises a beam jitter characterized by an offset of greater than 0.1 millimeter.

In some embodiments, the system further comprises a particle beam source configured to generate the particle beam. In some embodiments, the particle beam source is a wakefield accelerator system. In some embodiments, the wakefield accelerator system is driven by a laser. In some embodiments, the wakefield accelerator system is driven by a particle beam. In some embodiments, the particle beam source is a radiofrequency accelerator.

In some embodiments, the first aperture is configured to limit a transverse pointing error and a beam size to form the portion of the particle beam. In some embodiments, the first aperture is configured to select a centroid energy and an energy range of the particle beam to form the portion of the particle beam. In some embodiments, the first aperture is configured to select a centroid energy range from the particle beam with an energy greater than 5 MeV to form the portion of the particle beam. In some embodiments, the centroid energy is greater than 50 MeV. In some embodiments, the centroid energy is greater than 100 MeV. In some embodiments, the first aperture defines a virtual source point of the portion of the beam. In some embodiments, the first aperture is a pinhole. In some embodiments, the first aperture is a slit. In some embodiments, the first aperture is a combination of slits. In some embodiments, the first aperture is fixed. In some embodiments, the first aperture is adjustable along the axis of propagation. In some embodiments, the first aperture is adjustable along one or more axes not colinear with the axis of propagation. In some embodiments, the jitter of the portion of the particle beam following the first aperture is less than the particle beam before the first aperture.

In some embodiments, the virtual source energy is controlled by the location of the first aperture. In some embodiments, the portion of the particle beam comprises a deviation in the centroid energy of the particle beam from the virtual source of less than 10% of the centroid energy. In some embodiments, the energy spread around the centroid energy is less than 1% of the centroid energy. In some embodiments, the energy spread around the centroid energy is less than 0.1% of the centroid energy.

In some embodiments, the telescopic subsystem is configured to perform a variable transverse demagnification from the virtual source to the sample area. In some embodiments, the telescopic subsystem is tunable. In some embodiments, the telescopic subsystem further comprises two or more magnetic quadrupoles. In some embodiments, the two or more magnetic quadrupoles are adjustable. In some embodiments, the two or more magnetic quadrupoles are adjustable along the axis of propagation. In some embodiments, the telescopic subsystem comprises a magnetic solenoid. In some embodiments, the telescopic subsystem comprises a DC or a pulsed magnetic field. In some embodiments, the telescopic subsystem possesses a demagnification ratio of greater than 5:1. In some embodiments, the telescopic subsystem possesses a demagnification ratio of greater than 50:1. In some embodiments, the telescopic subsystem possesses a demagnification ratio of greater than 100:1.

In some embodiments, the system further comprises a device under test, wherein the sample area comprises the device under test. In some embodiments, the system further comprises a sample chamber, wherein the sample chamber comprises the sample area. In some embodiments, the demagnified image of the virtual source resides in the sample chamber. In some embodiments, the demagnified image of the virtual source in the sample chamber has a transverse size of 10 micron. In some embodiments, the demagnified image of the virtual source in the sample chamber has a longitudinal size of 2000 femtoseconds. In some embodiments, the sample chamber further comprises a particle beam detector. In some embodiments, the sample chamber further comprises a charged particle catch. In some embodiments, the charged particle catch is a charge detector. In some embodiments, the charge detector is calibrated.

In some embodiments, the system further comprises a first and second dispersive element along the axis of propagation, wherein the first dispersive element is before the first aperture, and wherein the second dispersive element is after the first aperture. In some embodiments, the first dispersive element comprises a first dipole and a second dipole, and wherein the second dispersive element comprises a third dipole and a fourth dipole. In some embodiments, the dispersive element is configured to further define the beam energy and energy spread. In some embodiments, the dispersive element is configured to reduce the particle beam energy deviation as compared to the particle beam energy deviation upon introduction. In some embodiments, the dispersive element is configured to reduce the particle beam energy variation to less than 1%. In some embodiments, the dispersive element is configured to reduce the particle beam energy variation by greater than 0.1%.

In some embodiments, the system further comprises a beam stop positioned along the axis of propagation after the sample area. In some embodiments, the system is further configured to stabilize the energy variations of the output beam. In some embodiments, the system is further configured to stabilize the charge fluctuation of the output beam.

In an aspect, the present disclosure provides a method for stabilizing a particle beam. In some embodiments, the method comprises: (a) providing a particle beam; (b) sampling a portion of the particle beam by passing the particle beam through a first aperture, wherein the sampling comprises clipping an edge of the particle beam with the first aperture to form a virtual source; (c) demagnifying the portion of the particle beam from the virtual source with a telescopic subsystem; and (d) directing the portion of the particle beam toward a sample area, wherein a pointing stability of the portion of the particle beam on the sample area is improved relative to the pointing stability of the particle beam.

In some embodiments, the method at (b) further comprises: (i) stabilizing a transverse beam jitter using the first aperture; (ii) forming the virtual source of the stabilized portion of the particle beam using a second aperture; (iii) stabilizing a beam energy and an energy spread of the portion of the beam using the second aperture; and imaging the virtual source onto a device under test such that a transverse spot size is smaller than 1 μm.

In some embodiments, the particle beam in (a) has an energy greater than 5 MeV. In some embodiments, the particle beam in (a) has an energy greater than 50 MeV. In some embodiments, the particle beam energy is greater than 100 MeV. In some embodiments, the particle beam energy is greater than 1000 MeV. In some embodiments, the particle beam in (a) comprises a beam jitter characterized by a deviation in angle of greater than 1 milliradian. In some embodiments, the particle beam in (a) is from a particle beam source, wherein the particle beam source is a wakefield accelerator system. In some embodiments, the particle beam in (a) is from a particle beam source, wherein the particle beam source is an RF accelerator system.

In some embodiments, the portion of the particle beam sampled in (b) is a central portion. In some embodiments, the method at (b) further comprises sampling a central portion of the particle beam with an energy greater than 5 MeV. In some embodiments, the method at (b) further comprises sampling a central portion of the particle beam with an energy greater than 50 MeV. In some embodiments, a position of the first aperture in (b) may be adjusted, altering the sampled energy. In some embodiments, the method at (b) further comprises clipping the edges of the particle beam, wherein the clipping reduces the variation in the centroid energy of the particle beam from the virtual source to less than 0.2%.

In some embodiments, the pointing stability is improved by decreasing a particle beam jitter by at least 60% relative to the stability of the provided particle beam. In some embodiments, the pointing stability is improved by decreasing a particle beam jitter by at least 80% relative to the stability of the provided particle beam. In some embodiments, the pointing stability is improved by decreasing a particle beam jitter to no greater than 0.5 milliradian. In some embodiments, the virtual source is imaged to a less than 10 micron spot on the device under test.

In an aspect, the present disclosure provides a method for stabilizing a particle beam. In some embodiments, the method comprises: (a) providing a particle beam; (b) sampling a portion of the particle beam by passing the particle beam through a first aperture, wherein the sampling comprises clipping an edge of the particle beam with the first aperture to form a virtual source; (c) demagnifying the portion of the particle beam from the virtual source with a telescopic subsystem; and (d) directing the portion of the particle beam toward a sample area, wherein an energy spread of the portion of the particle beam on the sample area is improved relative to the energy spread of the particle beam.

In some embodiments, the particle beam in (a) has an energy spread of at least ±10 MeV. In some embodiments, the particle beam in (a) has an energy greater than 5 MeV. In some embodiments, the particle beam in (a) has an energy greater than 50 MeV. In some embodiments, the particle beam in (a) is from a particle beam source, wherein the particle beam source is a wakefield accelerator system. In some embodiments, the particle beam in (a) is from a particle beam source, wherein the particle beam source is an RF accelerator system.

In some embodiments, the portion of the particle beam sampled in (b) is a central portion. In some embodiments, the method at (b) further comprises sampling a central portion of the particle beam with an energy greater than 5 MeV. In some embodiments, the method at (b) further comprises sampling a central portion of the particle beam with an energy greater than 50 MeV. In some embodiments, a cross sectional area of the first aperture in (b) may be adjusted, wherein the energy spread is reduced. In some embodiments, enlarging the cross sectional area of the first aperture increases the energy acceptance. In some embodiments, shrinking the cross sectional area of the first aperture decreases the energy acceptance. In some embodiments, the energy acceptance of the portion of the particle beam is reduced to ±5 MeV. In some embodiments, the energy acceptance of the portion of the particle beam is reduced to ±1 MeV. In some embodiments, the virtual source is imaged to a less than 10 micron spot on the device under test.

In an aspect, the present disclosure provides a method for stabilizing a particle beam, the method comprising: (a) providing a particle beam; (b) sampling a portion of the particle beam by passing the particle beam through a first aperture, wherein the sampling comprises clipping an edge of the particle beam with the first aperture to form a virtual source; (c) demagnifying the portion of the particle beam from the virtual source with a telescopic subsystem; and (d) directing the portion of the particle beam toward a sample area, wherein a charge fluctuation of the portion of the particle beam on the sample area is improved relative to the charge fluctuation of the particle beam.

In some embodiments, the particle beam in (a) has an energy greater than 5 MeV. In some embodiments, the particle beam in (a) has an energy greater than 50 MeV. In some embodiments, the particle beam in (a) is from a particle beam source, wherein the particle beam source is a wakefield accelerator system. In some embodiments, the charge distribution of the particle beam in (a) is non-uniform.

In some embodiments, the central portion of the particle beam in (a) possesses a smaller charge density fluctuation than a charge density fluctuation in the outer regions of the particle beam. In some embodiments, a cross sectional area of the first aperture in (b) may be adjusted, wherein the charge density fluctuation is altered. In some embodiments, enlarging the cross sectional area of the first aperture increases the charge density fluctuation across the portion of the particle beam. In some embodiments, shrinking the cross sectional area of the first aperture decreases the charge density fluctuation across the portion of the particle beam. In some embodiments, the charge fluctuation across the portion of the particle beam is reduced by greater than 50% relative to the charge fluctuation of the particle beam.

Additional advantages of the disclosed devices, systems, and methods will be set forth in part in the description which follows, and in part will be obvious from the description. The advantages of the disclosed devices, systems, and methods will be realized and attained by the elements and combinations particularly pointed out in the appended claims. It is to be understood that both the foregoing general description and the following detailed description are exemplary and explanatory only and are not restrictive of the disclosed devices, systems, and methods, as claimed.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the disclosure are set forth with particularity in the appended claims. A better understanding of the features and advantages of the present disclosure will be obtained by reference to the following detailed description that sets forth illustrative embodiments, in which the principles of the disclosure are utilized, and the accompanying drawings (also “Figure” and “FIG.” herein), of which:

FIG. 1 is an example system for stabilizing a particle beam, in accordance with embodiments herein.

FIG. 2A is an example system for beam stabilization with a 4-dipole dispersive element, in accordance with embodiments herein.

FIG. 2B is a segment of the system of FIG. 2A, displaying the particle beam, first aperture, and the dispersive element, in accordance with embodiments herein.

FIG. 2C is a segment of the system of FIG. 2A, displaying the dispersive element, telescopic subsystem, and sample area, in accordance with embodiments herein.

FIG. 3 is an example system for beam stabilization with a 2-dipole dispersive element, in accordance with embodiments herein.

FIG. 4 is an example system for beam stabilization with a 1-dipole dispersive element, in accordance with embodiments herein.

FIG. 5A is an example electromagnetic quadrupole magnet, in accordance with embodiments herein.

FIG. 5B is an example permanent quadrupole magnet, in accordance with embodiments herein.

FIG. 6 is an example method for stabilizing a particle beam to improve beam stability, in accordance with embodiments herein.

FIG. 7 is an example method for stabilizing a particle beam to improve energy spread, in accordance with embodiments herein.

FIG. 8 is an example method for stabilizing a particle beam to improve charge fluctuation, in accordance with embodiments herein.

### DETAILED DESCRIPTION

The devices, methods, and systems described herein may be understood more readily by reference to the following detailed description of specific aspects of the disclosed subject matter and the Examples included therein. In this specification and in the claims that follow, reference will be made to a number of terms, which shall be defined to have the following meanings.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” or “less than or equal to” precedes the first numerical value in a series of two or more numerical values, the term “no more than,” “less than,” or “less than or equal to” applies to each of the numerical values in that series of numerical values. For example, less than or equal to 3, 2, or 1 is equivalent to less than or equal to 3, less than or equal to 2, or less than or equal to 1.

Inventive embodiments herein contemplate numerical ranges. When ranges are present, the ranges include the range endpoints. Additionally, every sub range and value within the range is present as if explicitly written out.

The term “about” or “approximately” may mean within an acceptable error range for the particular value, which will depend in part on how the value is measured or determined, e.g., the limitations of the measurement system. For example, “about” may mean within 1 or more than 1 standard deviation, per the practice in the art. Alternatively, “about” may mean a range of up to 20%, up to 10%, up to 5%, or up to 1% of a given value. Where particular values are described in the application and claims, unless otherwise stated the term “about” meaning within an acceptable error range for the particular value may be assumed.

### Particle Beam Stabilization

Disclosed herein are systems and methods for stabilizing particle beams. A system for stabilizing a particle beam may be useful for precision electron-based test systems. Single-event testing of electronics is often done with heavy ions, pulsed laser systems, or high-energy pulsed x-rays, exceeding 80 keV. In the case of heavy ions, the ions are accelerated to high energy and aimed at the electronics to be tested. As the heavy ions pass through the electronics they ionize the material along their path. This ionization can create single-event upsets in the electronics and therefore inform the study team of the susceptibility of the electronics to radiation events. Pulsed laser systems have been used as an alternative to heavy ions, but the method by which they ionize the electronics is different than cosmic rays, furthermore their penetration ability is limited and so they are less suitable for many of the newer electronics particularly those using 3D fabrication methods. Similarly high-energy x-rays ionize the electronics in a manner different to cosmic rays and so may be limited in ability as they do not provide one-to-one correspondence to a heavy ion.

In single-event effect testing, particle bunch size may be an element for testing electronics. When utilizing electrons as the particle, improved testing of electronics may depend on the electron packet having a controlled transverse and longitudinal size while maintaining a high energy. This ensures such a particle bunch has the same impact on the electronics that a heavy ion does. By controlling the transverse and longitudinal size and the energy of the electron bunch, the electron packet can be maintained at a useful size while reducing transverse scattering and improving penetration of the electron packet through the device under test. By maintaining a high energy, the device under test may readily be penetrated by the electron packet while reducing transverse scatter. Therefore, for efficient testing with an electron packet, it may be beneficial to control and optimize the transverse size, longitudinal size, and packet energy of a particle bunch.

The present disclosure provides at least some of the following benefits: utilizes laser wakefield accelerator technology as the source of high-energy electron packets; minimized energy of unwanted electrons through use of virtual source; provides transverse position, transverse size, and transverse divergence precision of virtual source; allows definition of centroid energy and energy spread of virtual source; enables point-to-point imaging and variable demagnification; and allows for homogeneity of beam and allows adjustment of beam charge during use.

The systems, devices, and methods as discussed herein may be used for commercial, medical, research, or other suitable purposes. The systems, devices, and methods as discussed herein may be configured for single event effect testing, which may evaluate electronic components for susceptibility to radiation-induced disruptions. The systems, devices, and methods as discussed herein may be configured for medical purposes. Medical purposes may include surgery, sterilization, radiotherapy, or other medical procedures or diagnostic purposes.

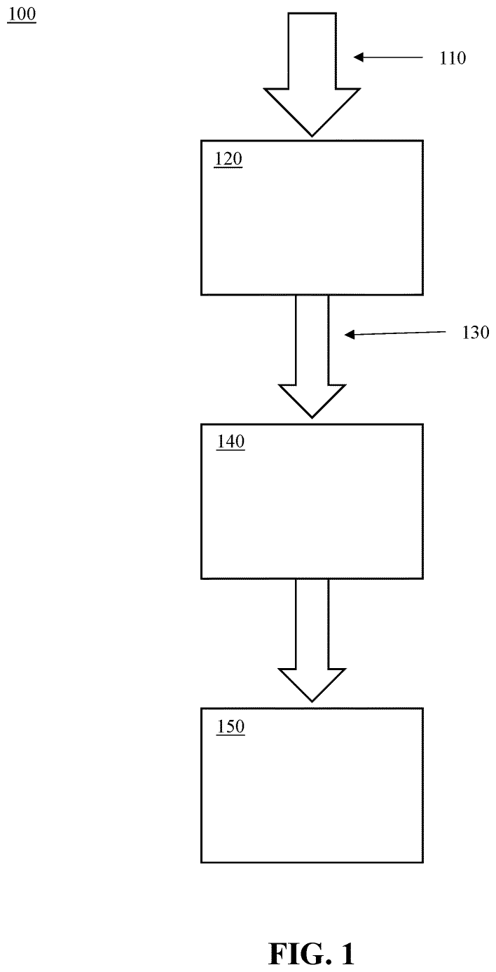

The disclosure provides systems 100, for example, as provided in FIG. 1. The systems may comprise a particle beam directed towards a first aperture 120. The first aperture is configured to form a virtual source 130. The virtual source samples a portion of the particle beam to be directed downstream toward a telescopic subsystem 140. The telescopic subsystem is configured to image a portion of the particle beam onto a sample area 150.

Single event effect testing may be done with heavy ions. Heavy ions may be those delivered by cyclotrons, synchrotrons, and linear accelerators. In some examples, heavy ions may be those with a molecular weight greater than a proton. In some examples, heavy ions may be those with a molecular weight greater than 1, greater than 10, greater than 50, greater than 100, greater than 200, or greater than 250. In some examples, heavy ions may be those with a molecular weight greater than H or greater than He.

High energy pulsed X-rays may be utilized, where the high energy pulsed X-rays may have a minimum energy. The high energy may be considered greater than 100 keV, greater than 1 MeV, greater than 10 MeV, greater than 100 MeV, greater than 500 MeV, greater than 1 GeV, greater than 5 GeV, greater than 10 GeV, greater than 20 GeV, greater than 50 GeV. High-energy electrons can be used as a surrogate to heavy ions. One advantage over lasers and x-rays is improved penetration capability, while providing an ionization mechanism similar to the ionization induced by a heavy ion. This advantage is optimized when an electron bunch is generated with a chosen amount of electrons and the electron bunch is focused transversely to a small size with a short bunch length. In that case, the bunch impacts the electronics in a manner indistinguishable from a heavy ion. Such a precision electron-based single-event test system can then be used as a one-to-one substitute for a much bigger heavy-ion facility.

Disclosed herein is a precision electron-based single effect test system. In some examples, the system may comprise a particle beam. In some examples, the system may further comprise a first aperture. In some examples, the system further may comprise a first aperture on an axis of propagation of the particle beam. In some examples, the system may further comprise a first aperture wherein the first aperture may further form a virtual source configured to sample a portion of the particle beam. In some examples, the system may further comprise a telescopic subsystem for the portion of the particle beam from the virtual source. In some examples, the system may further comprise a telescopic subsystem configured to image the portion of the particle beam onto a sample area. In some examples, the system may further comprise a first aperture configured to stabilize at least a pointing stability of the portion of the particle beam.

The system may be configured to stabilize a pointing stability of the particle beam. In some examples, the system may be configured to stabilize the energy variation of the particle beam. In some examples, the system may be configured to stabilize the energy acceptance of the delivered particle beam. In some examples, the system may be configured to stabilize the charge fluctuation of the particle beam. In some examples, the system may be configured to stabilize the one or more of the above of the particle beam.

The system may be configured to stabilize a pointing stability of a portion of the particle beam. Stability of a portion of the beam may include systems configured to stabilize the energy variation of a portion of the particle beam, stabilize the charge fluctuation of a portion of the particle beam, stabilize the pointing stability of an output beam, where the output beam is a portion of the particle beam, stabilize the energy variation of an output beam, where the output beam is a portion of the particle beam, or stabilize the charge fluctuation of an output beam, where the output beam is a portion of the particle beam. In some examples, the system may be positioned within a vacuum chamber.

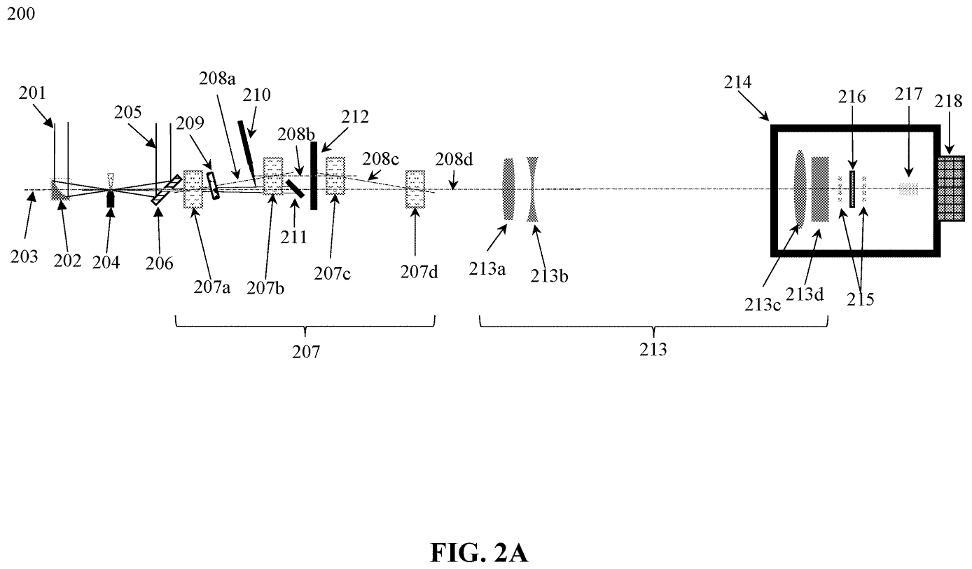

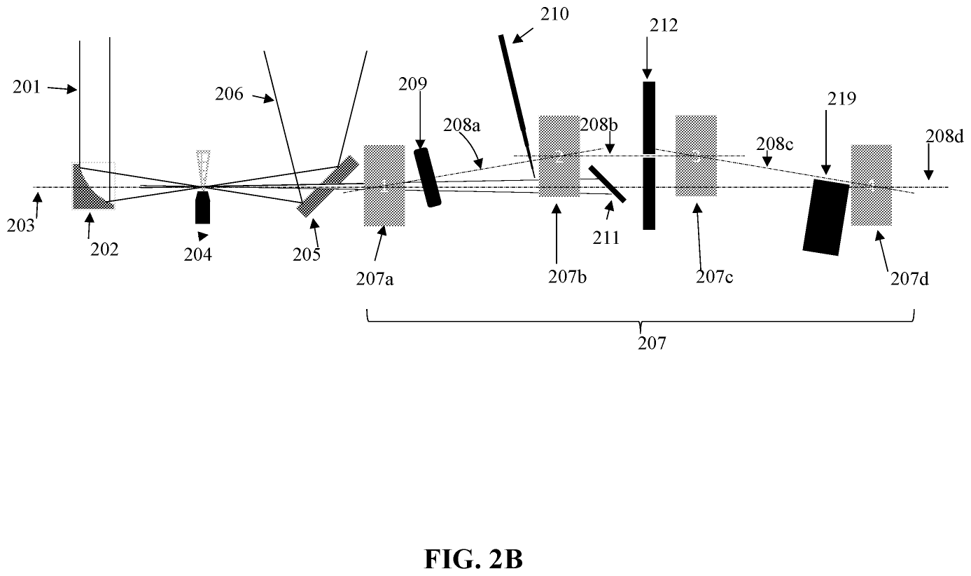

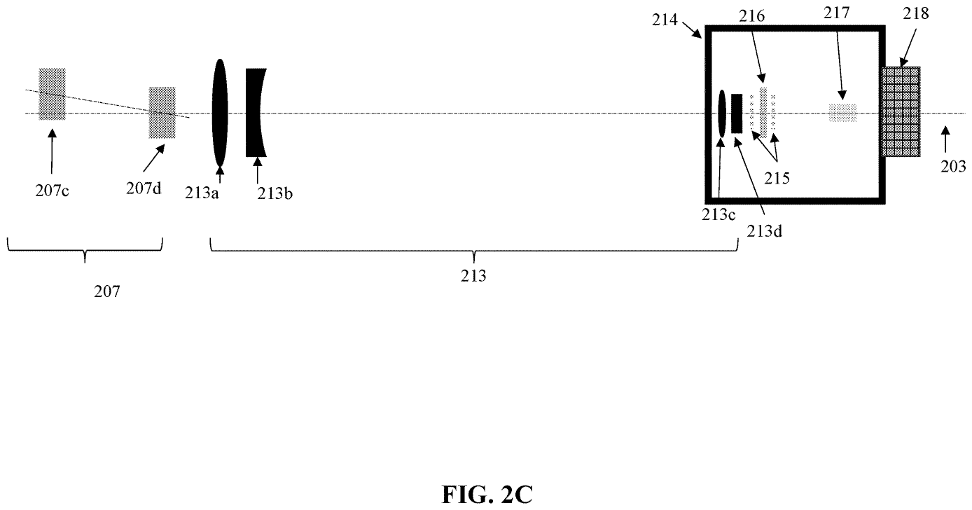

As shown in FIG. 2A, an example system for beam stabilization 200 is provided. In some examples, the particle source is a laser wakefield accelerator. An input laser beam 201 is directed toward the system and the laser beam is redirected by a first mirror 202, which is an off axis parabola here. The first mirror 202 directs the laser beam along an axis of propagation 203 towards a target 204, where the particle beam is formed and travels along the axis of propagation. The particle beam and residual laser input beam then interact with a second aperture 206, resulting in the reflection of the majority of the laser input beam 205 and allowing a portion of the particle beam to continue to travel through. The particle beam then passes through a dispersive element 207, which comprises 4 dipoles 207a, 207b, 207c, 207d. The dispersive element bends the particle beam flow direction off of the initial axis of propagation 208a, 208b, 208c, and, in this case, ultimately returns the particle beam path to the initial axis of propagation 208d. During this time when the beam is being bent by the dispersive element 207, the beam further interacts with the calibrated integrating current transformer (ICT) 209, stepped diffuser 210, and first aperture 212, wherein the first aperture forms a virtual source. A second mirror 211 is used to remove the remaining laser input beam. The particle beam exiting the virtual source is then directed to a telescopic subsystem 213, which comprises 4 quadrupoles 213a, 213b, 213c, 213d. The virtual source is subsequently directed to a sample chamber 214. The sample chamber comprises a diamond amplifier 215, a device under test 216, and a calibrated Faraday cup 217. The end of the sample chamber is abutted by a beam stop 218.

As shown in FIGS. 2B and 2C, the example system is provided in two parts. In FIG. 2B, the particle beam, first aperture, and the dispersive element are highlighted. In this example, an input laser beam 201 is directed toward the system and the laser beam is redirected by a first mirror 202, which is an off axis parabola here. The first mirror 202 directs the laser beam along an axis of propagation 203 towards a target 204, where the particle beam is formed and travels along the axis of propagation. The particle beam and residual input laser beam then interact with a second aperture 206, resulting in the reflection of the remaining input laser beam 205 and allowing a portion of the particle beam to continue to travel through. The particle beam then passes through a dispersive element 207, which comprises 4 dipoles 207a, 207b, 207c, 207d. The dispersive element bends the particle beam flow direction off of the initial axis of propagation 208a, 208b, 208c, and, in this case, ultimately returns the particle beam path to the initial axis of propagation 208d. During this time when the beam is being bent by the dispersive element 207, the beam further interacts with the calibrated ICT 209, stepped diffuser 210, first aperture 212, and a beam stripper 219, wherein the first aperture forms a virtual source.

In FIG. 2C, the virtual source continues from the 2 dipoles 207c, 207d of the dispersive element and is then directed to a telescopic subsystem 213, which comprises 4 quadrupoles 213a, 213b, 213c, 213d. The virtual source is subsequently directed to a sample chamber 214. The sample chamber comprises a diamond amplifier 215, a device under test 216, and a calibrated Faraday cup 217. The end of the sample chamber is abutted by a beam stop 218.

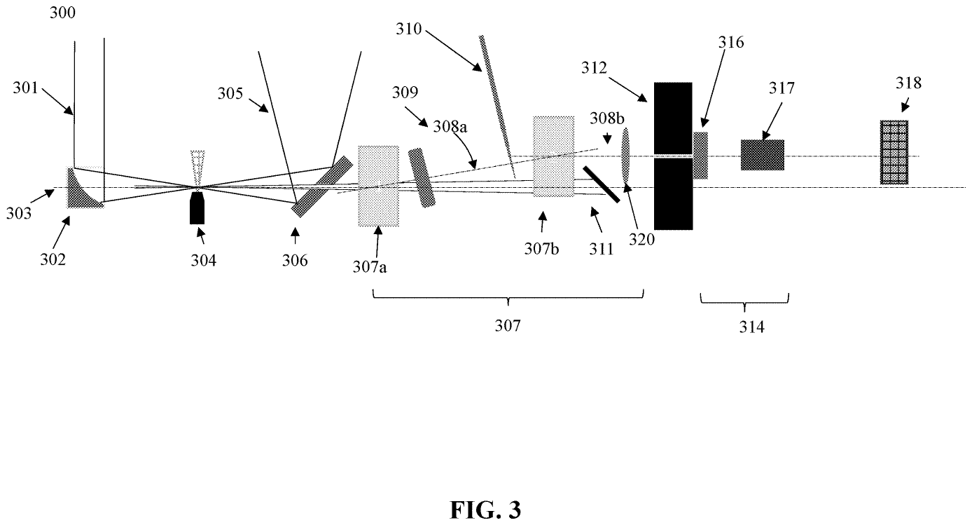

As shown in FIG. 3, an example test system for beam stabilization 300 is provided. In this example, the particle source is a laser wakefield accelerator. An input laser beam 301 is directed toward the system and the laser beam is redirected by a first mirror 302, which is an off axis parabola here. The first mirror 302 directs the beam along an axis of propagation 303 towards a target 304, where the particle beam is formed and travels along the axis of propagation. The particle beam and residual input laser beam then interact with a second aperture 306, resulting in the reflection of the remaining input laser beam 305 and allowing a portion of the particle beam to continue to travel through. The particle beam then passes through a dispersive element 307, which comprises 2 dipoles 307a, 307b. The dispersive element bends the particle beam flow direction off of the initial axis of propagation 308a, 308b. During this time when the beam is being bent by the dispersive element 307, the beam 320 further interacts with the calibrated ICT 309 and stepped diffuser 310. The particle beam is then directed through the first aperture 312, wherein the first aperture forms a virtual source. The virtual source is subsequently directed to a sample area 314. The sample chamber comprises a device under test 316 and a calibrated Faraday cup 317. The end of the sample chamber is abutted by a beam stop 318.

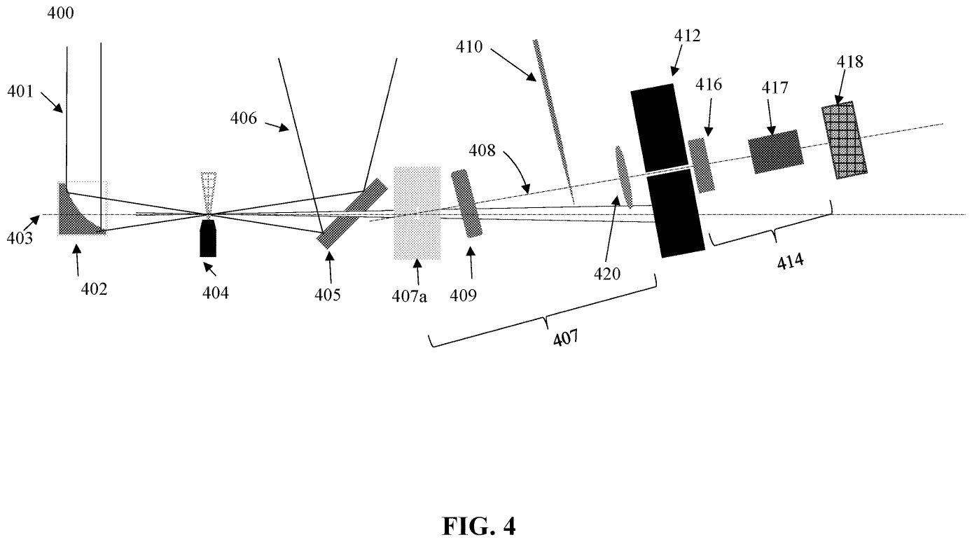

As shown in FIG. 4, an example test system for beam stabilization 400 is provided. In this example, the particle source is a laser wakefield accelerator. An input laser beam 401 is directed toward the system and the laser beam is redirected by a first mirror 402, which is an off axis parabola here. The first mirror 402 directs the beam along an axis of propagation 403 towards a target 404, where the particle beam is formed and travels along the axis of propagation. The particle beam and residual input laser beam then interact with a second aperture 405, resulting in the reflection of the remaining input laser beam 406 and allowing a portion of the particle beam to continue to travel through. The particle beam then passes through a dispersive element 407, which comprises 1 dipole 407a. The dispersive element bends the particle beam flow direction off of the initial axis of propagation 408. During this time when the beam is being bent by the dispersive element 407, the beam further interacts with the calibrated ICT 409 and stepped diffuser 410. The particle beam 420 is then directed through the first aperture 412, wherein the first aperture forms a virtual source. The virtual source is subsequently directed to a sample area 414. The sample chamber comprises a device under test 416 and a calibrated Faraday cup 417. The end of the sample chamber is abutted by a beam stop 418.

### Particle Beam

The system may comprise a particle beam. The particle beam may be an electron beam, proton beam, or neutron beam.

The particle beam may be formed as a result of interaction with a target. In some examples, the particle beam may be formed as a result of interaction with a laser and a target. In some examples, the particle beam may be formed as a result of interaction with an input beam and a target. In some examples, the particle beam may be formed from an ionizing process. In some examples, the particle beam may be formed from a thermionic process. In some examples, the target can comprise any suitable material. In some examples, the target can comprise a metal, a metalloid, a nonmetal, derivatives thereof, or combinations thereof. In some examples, the target can, for example, comprise a semiconductor, a ceramic, a transparent conducing oxide, a polymer, a carbon material, a metal (e.g., an alloy), a nitride, an oxide, a silicide, a germanide, a carbide, a derivative thereof, or a combination thereof.

The target may be elemental and can comprise H, He, Li, Be, B, C, Mg, Al, Si, P, S, Ca, Sc, Ti, V, Cr, Mn, Fe, Co, Ni, Cu, Zn, Ga, Ge, As, Se, Sr, Y, Zr, Nb, Mo, Tc, Ru, Rh, Pd, Ag, Cd, In, Sn, Sb, Te, Cs, Ba, Hf, Ta, W, Re, Os, Ir, Pt, Au, Hg, Tl, Pb, Bi, Po, La, Ce, Pr, Nd, Pm, Sm, Eu, Gd, Tb, Dy, Ho, Er, Tm, Yb, or a combination thereof.

The target may comprise a metal. In some examples, the target may comprise a metal selected from the group comprising of Li, Be, Mg, Al, Ca, Sc, Ti, V, Cr, Mn, Fe, Co, Ni, Cu, Zn, Ga, Sr, Y, Zr, Nb, Mo, Tc, Ru, Rh, Pd, Ag, Cd, In, Sn, Ba, Hf, Ta, W, Re, Os, Ir, Pt, Au, Hg, Tl, Pb, Bi, La, Ce, Pr, Nd, Pm, Sm, Eu, Gd, Tb, Dy, Ho, Er, Tm, Yb, and combinations thereof. In some examples, the target may comprise a metal selected from the group comprising of Al, Cr, Mn, Fe, Co, Ni, Cu, Mo, Pd, Ag, Pt, Au, and combinations thereof.

The target may comprise a fluid (e.g., a liquid, a gas, any suitable gaseous material, a fluid comprising the ablated target).

The particle beam may be generated from a particle beam source. In some examples, the particle beam source may be located along an axis of propagation. In some examples, the particle beam source may be located along a second axis different from the axis of propagation. The particle beam source may be cathode-ray tubes, an electron gun, an ion source, a photocathode, an accelerator system, a particle accelerator, a plasma accelerator, a wakefield accelerator system, a radiofrequency accelerator, or a muon accelerator. In some examples, the wakefield accelerator system may be driven by a laser. In some examples, the wakefield accelerator system may be driven by a particle beam.

The particle beam may comprise one distinct beam. In some examples, the particle beam may comprise one or more distinct beams. In some examples, the particle beam may comprise two distinct beams. In some examples, the particle beam may comprise three distinct beams. In some examples, the particle beam may comprise four distinct beams. In some examples, the particle beam may comprise more than four distinct beams. In some examples, the particle beam may comprise a beam array. In some examples, the particle beam may be uniform. In some examples, the particle beam may be a continuous wave. In some examples, the particle beam may fluctuate. In some examples, the particle beam may be pulsed. In some examples, the particle beam may be time-dependent pulsed, like nanosecond pulse, picosecond pulse, or femtosecond pulse. In some examples, the particle beam may be stable. In some examples, the particle beam may be repeatable.

The particle beam may have an energy, wherein the particle beam may be high energy. In some cases, the high energy electron beam may have an energy greater than about 1 MeV, greater than about 5 MeV, greater than about 10 MeV, greater than about 50 MeV, greater than about 100 MeV, greater than about 150 MeV, greater than about 200 MeV, greater than about 250 MeV, greater than about 500 MeV, greater than about 1000 MeV, greater than 5 GeV, greater than 10 GeV, greater than 50 GeV, greater than 100 GeV. In some cases, the energy may be from about 1 MeV to about 1000 MeV, from about 1 MeV to about 50 MeV, from about 50 MeV to about 100 MeV, from about 100 MeV to about 150 MeV, from about 150 MeV to about 200 MeV, from about 200 MeV to about 250 MeV, from about 250 MeV to about 500 MeV, from about 500 MeV to about 750 MeV, from about 750 MeV to about 1000 MeV, from about 1000 MeV to about 10 GeV, or from about 10 GeV to about 100 GeV.

The particle beam may have an energy, wherein the particle beam may have a minimum energy. In some cases, the minimum energy may be greater than about 50 MeV, greater than about 100 MeV, greater than about 150 MeV, greater than about 200 MeV, greater than about 250 MeV, greater than about 500 MeV, greater than about 1000 MeV, or greater than about 1000 MeV.

The particle beam may comprise a beam jitter (e.g. angular beam jitter, transverse beam jitter). In some examples, the particle beam jitter may be a deviation from the particle beam path. The particle beam jitter deviation may be greater than about 0.01 milliradian, greater than about 0.1 milliradian, greater than about 1 milliradian, greater than about 10 milliradians. In some examples, the particle beam jitter deviation may be from about 0.01 milliradian to about 0.1 milliradian, from about 0.1 milliradian to about 1 milliradian, from about 1 milliradian to about 2.5 milliradians, from about 2.5 milliradians to about 5 milliradians, from about 5 milliradians to about 7.5 milliradians, or from about 7.5 milliradians to about 10 milliradians.

The particle beam may comprise a beam jitter, like transverse beam jitter. The particle beam jitter deviation may be greater than about 0.01 millimeter, greater than about 0.1 millimeter, greater than about 1 millimeter, greater than about 10 millimeters. In some cases, the particle beam jitter deviation may be from about 0.01 millimeter to about 0.1 millimeter, from about 0.1 millimeter to about 1 millimeter, from about 1 millimeter to about 2.5 millimeters, from about 2.5 millimeters to about 5 millimeters, from about 5 millimeters to about 7.5 millimeters, or from about 7.5 millimeters to about 10 millimeters.

### First Aperture

The system may comprise a first aperture. The first aperture may be along the particle beam path, along the axis of propagation, or off of the axis of propagation. In some examples, the system may comprise a single aperture, wherein the single aperture may be the first aperture.

The system may comprise one aperture. In some examples, the system may comprise more than one aperture. In some examples, the system may comprise two apertures. In some examples, the system may comprise more than two apertures. In some examples, the system may comprise three apertures. In some examples, the system may comprise more than three apertures. In some examples, the one aperture present may be the first aperture.

The first aperture may be configured to interact with the particle beam. In some examples, the first aperture may be configured to interact with a portion of the particle beam. In some examples, the first aperture may be configured to limit the particle beam pointing error. In some examples, the first aperture may be configured to limit the particle beam transverse pointing error. In some examples, the first aperture may be configured to limit the particle beam transverse pointing error to form the portion of the particle beam. In some examples, the first aperture may be configured to limit the beam size of the particle beam. In some examples, the first aperture may be configured to limit the particle beam size to form the portion of the particle beam. In some examples, the first aperture may be configured to stabilize the pointing stability of the particle beam. In some examples, the first aperture may be configured to stabilize the pointing stability of the particle beam onto a sample area.

The first aperture may be a slit. In some examples, the first aperture may be a plurality of slits, combination of slits, parallel slits, intersecting slits, or slits orthogonal to one another. In some examples, the first aperture may be a pinhole. In some examples, the first aperture may be a plurality of pinholes. In some examples, the plurality of pinholes may be identical or may vary, with variances in shape, in cross-sectional size, or in diameter.

The first aperture may have a shape (e.g., a triangle, a square, a rectangle, a pentagon, a circle, a hole). In some examples, the first aperture may be any suitable shape.

The first aperture may have a cross-sectional length. In some examples, the cross-sectional length may be from around 10 μm (micrometer) to about 100 mm (millimeter). In some examples, the cross-sectional length may be from about 10 μm to about 100 μm. In some examples, the cross-sectional length may be from about 100 μm to about 1 mm. In some examples, the cross-sectional length may be from about 1 mm to about 25 mm. In some examples, the cross-sectional length may be from about 25 mm to about 50 mm. In some examples, the cross-sectional length may be from about 50 mm to about 75 mm. In some examples, the cross-sectional length may be from about 75 mm to about 100 mm. In some examples, the cross-sectional length may be about 10 μm. In some examples, the cross-sectional length may be about 100 μm. In some examples, the cross-sectional length may be about 1 mm. In some examples, the cross-sectional length may be about 25 mm. In some examples, the cross-sectional length may be about 50 mm. In some examples, the cross-sectional length may be about 75 mm. In some examples, the cross-sectional length may be about 100 mm. In some examples, the cross-sectional length may be about 100 μm.

The first aperture may have a diameter. The diameter may be from around 10 μm (micrometer) to about 25 mm (millimeter). The diameter may range from about 10 μm to about 100 μm, about 100 μm to about 1 mm, or from about 1 mm to about 25 mm. The diameter may be about 10 μm, about 100 μm, about 1 mm, about 25 mm, or about 100 μm.

The first aperture may be positioned on a surface. In some examples, the surface may be an opaque surface. In some examples, the surface may be a metal plate. In some examples, the plate may comprise a plurality of metals. In some examples, the plate may comprise a single metal. In some examples, the plate may comprise a metal selected from the group comprising of Li, Be, Mg, Al, Ca, Sc, Ti, V, Cr, Mn, Fe, Co, Ni, Cu, Zn, Ga, Sr, Y, Zr, Nb, Mo, Tc, Ru, Rh, Pd, Ag, Cd, In, Sn, Ba, Hf, Ta, W, Re, Os, Ir, Pt, Au, Hg, Tl, Pb, Bi, La, Ce, Pr, Nd, Pm, Sm, Eu, Gd, Tb, Dy, Ho, Er, Tm, Yb, and combinations thereof. In some examples, the plate may comprise tungsten (W). In some examples, the surface may be a non-metal surface. In some examples, the surface may be a transparent surface. In some examples, the surface may be a glass surface. In some examples, the surface may be a reflective surface. In some examples, the surface may be a mirror. In some examples, the surface may be configured to act as a beam stop.

The first aperture may interact with the particle beam. In some examples, the first aperture may sample the particle beam. In some examples, the first aperture may sample a portion of the particle beam. In some examples, the first aperture may allow a portion of the particle beam to pass through. In some examples, the first aperture may allow from about 0% to about 25% of the particle beam to pass through. In some examples, the first aperture may allow from about 25% to about 50% of the particle beam to pass through. In some examples, the first aperture may allow from about 50% to about 75% of the particle beam to pass through. In some examples, the first aperture may allow from about 75% to about 99% of the particle beam to pass through. In some examples, the first aperture may result in a portion of the particle beam to pass through. In some examples, the portion of the particle beam may form a virtual source. In some examples, the first aperture may define a virtual source point. In some examples, the virtual source point may be of a portion of the beam.

The first aperture may be fixed. In some examples, the first aperture may be adjustable, such as adjustable along one or more axes, adjustable along the axis of propagation, adjustable along an axis not colinear with the axis of propagation, adjustable along an axis intersecting with the axis of propagation, or adjustable along an axis orthogonal with the axis of propagation.

The position of the first aperture may select a portion of the particle beam. In some examples, the position of the first aperture may select a portion of the particle beam near the center of the particle beam. In some examples, the position of the first aperture may select a portion of the particle beam away from the center of the particle beam. In some examples, the position of the first aperture may select a centroid energy of the particle beam. In some examples, the position of the first aperture may select a centroid energy of the particle beam forming a portion of the particle beam. In some examples, the position of the first aperture may select an energy range of the particle beam. In some examples, the position of the first aperture may select an energy range of the particle beam to form a portion of the particle beam.

The first aperture may select a portion of the particle beam, wherein the portion of the particle beam forms the virtual source. In some examples, the first aperture may select a centroid energy of the particle beam, wherein the centroid energy is equal to the virtual source energy. In some examples, the first aperture position may adjust the selected centroid energy, wherein the first aperture position may control the virtual source energy.

The position of the first aperture may select a centroid energy of the particle beam forming a portion of the particle beam. The centroid energy may form the portion of the particle beam. The centroid energy may be greater than about 1 MeV. The centroid energy may be greater than about 5 MeV, greater than about 10 MeV, greater than about 15 MeV, greater than about 20 MeV, greater than about 25 MeV, greater than about 50 MeV, greater than about 100 MeV, greater than about 150 MeV, greater than about 200 MeV, greater than about 250 MeV, greater than about 500 MeV, or greater than about 1000 MeV. The centroid energy may be from about 5 MeV to about 1000 MeV, from about 5 MeV to about 25 MeV, from about 25 MeV to about 50 MeV, from about 50 MeV to about 100 MeV, from about 100 MeV to about 250 MeV, from about 250 MeV to about 500 MeV, or from about 500 MeV to about 1000 MeV.

The first aperture may sample a portion of the particle beam. In some examples, the first aperture may reduce the jitter of the particle beam. In some examples, the first aperture may reduce the jitter of the particle beam in comparison to the beam jitter before interaction with the first aperture. In some examples, the jitter of the portion of the particle beam following the first aperture may be less than the particle beam before the first aperture. In some examples, the jitter of the portion of the particle beam following the first aperture may be greater than the particle beam before the first aperture.

The first aperture may be downstream of a quadrupole. The first aperture may be downstream of one or more quadrupoles. The first aperture may be positioned between a primary and secondary quadrupoles.

The portion of the particle beam may comprise a centroid energy. In some examples, the portion of the particle beam may comprise an energy spread around the centroid energy. The energy spread around the centroid energy of the portion of the particle beam may be, in some cases, less than about 20% of the centroid energy, less than about 10% of the centroid energy, less than about 5% of the centroid energy, less than about 1% of the centroid energy, less than about 0.5% of the centroid energy, less than about 0.1% of the centroid energy, or less than about 0.01% of the centroid energy.

### Telescopic Subsystem

The system may further comprise a telescopic subsystem. The telescopic subsystem may be configured to project the virtual source, direct the virtual source, focus the virtual source, defocus the virtual source, demagnify the virtual source, uniformly demagnify the virtual source, variably demagnify the virtual source, perform transverse demagnification of the virtual source, or perform variable transverse demagnification of the virtual source.

The telescopic subsystem may be configured to project the particle beam. In some examples, the telescopic subsystem may be configured to direct the particle beam. In some examples, the telescopic subsystem may be configured to focus the particle beam. In some examples, the telescopic subsystem may be configured to defocus the particle beam. In some examples, the telescopic subsystem may be configured to demagnify the particle beam. In some examples, the telescopic subsystem may be configured to uniformly demagnify the particle beam. In some examples, the telescopic subsystem may be configured to variably demagnify the particle beam. In some examples, the telescopic subsystem may be configured to perform transverse demagnification of the particle beam. In some examples, the telescopic subsystem may be configured to perform variable transverse demagnification of the particle beam. In some examples, the telescopic subsystem may be configured to perform chosen or fixed transverse demagnification of the particle beam.

The telescopic subsystem may possess a demagnification ratio. In some examples, the demagnification ratio may be from about 2:1 to about 500:1, which includes from about 2:1 to about 5:1, from about 5:1 to about 10:1, from about 10:1 to about 50:1, from about 50:1 to about 100:1,from about 100:1 to about 250:1, or from about 250:1 to about 500:1. The demagnification ratio may further be about 3:1, about 5:1, about 10:1, about 50:1,about 100:1, or about 500:1.

The telescopic subsystem may direct the virtual source. In some examples, the telescopic subsystem may direct the virtual source along an axis identical to the virtual source entry axis. In some examples, the telescopic subsystem may direct the virtual source along an axis different from the virtual source entry axis. In some examples, the telescopic subsystem may direct the virtual source along the axis of propagation. In some examples, the telescopic subsystem may direct the virtual source to the sample area. In some examples, the telescopic subsystem may be configured to image the virtual source onto the sample area. In some examples, the telescopic subsystem may direct the particle beam. In some examples, the telescopic subsystem may direct the particle beam along an axis identical to the particle beam entry axis. In some examples, the telescopic subsystem may direct the particle beam along an axis different from the particle beam entry axis. In some examples, the telescopic subsystem may direct the particle beam along the axis of propagation. In some examples, the telescopic subsystem may direct the particle beam to the sample area. In some examples, the telescopic subsystem may be configured to image the particle beam onto the sample area.

The telescopic subsystem may direct an electron bunch, wherein the electron bunch is present in the virtual source or the particle beam. The electron bunch may be long, short, or ultrashort. The electron bunch may have an energy, where the energy may be low, high, or ultra-high. In some examples, the electron bunch may be ultra-short and high energy.

The electron bunch may comprise a number of electrons. The electron bunch may comprise from about 10 electrons to about 10,000,000 electrons, such as from about 10 electrons to about 100 electrons, about 100 electrons to about 1000 electrons, 1000 electrons to about 10,000 electrons, about 10,000 electrons to about 100,000 electrons, about 100,000 electrons to about 1,000,000 electrons, or about 1,000,000 electrons to about 10,000,000 electrons. In some examples, the electron bunch may comprise more than 10,000,000 electrons.

The electron bunch may have a charge. In some examples, the electron bunch charge may be from about 1 picocoulomb to about 1 attocoulomb. The electron bunch may be from 1 picocoulomb to about 100 femtocoulombs, about 100 femtocoulombs to about 10 femtocoulombs, about 10 femtocoulombs to about 1 femtocoulomb, about 1 femtocoulomb to about 100 attocoulombs, about 100 attocoulombs to about 10 attocoulombs, about 10 attocoulombs to about 1 attocoulomb, or about 1 attocoulomb to about 0.1 attocoulombs.

The electron bunch may have a longitudinal duration. The longitudinal duration may be less than about 1 nanosecond, less than about 500 picoseconds, less than about 100 picoseconds, less than about 10 picoseconds, less than about 1 picosecond, less than about 500 femtoseconds, less than about 100 femtoseconds, or less than about 1 femtosecond.

The telescopic subsystem may comprise a magnetic solenoid. In some examples, the telescopic subsystem may comprise a magnetic field. In some examples, the magnetic field may be a DC magnetic field. In some examples, the magnetic field may be a pulsed magnetic field.

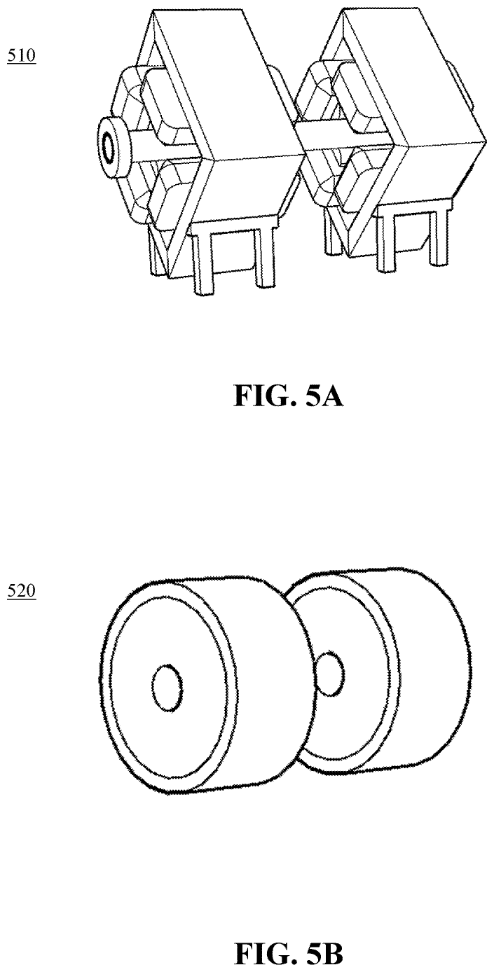

The telescopic subsystem may comprise a magnet. The magnet may be selected to optimize Courant-Snyder parameters, system efficiency, shorter length, etc. In some examples, the telescopic subsystem may comprise a plurality of magnets (e.g., one magnet, two magnets, three magnets, four magnets, more than four magnets). In some examples, the telescopic subsystem magnet may be a dipole. In some examples, the telescopic subsystem may comprise a plurality of dipoles. In some examples, the telescopic subsystem magnet may be a quadrupole. In some examples, the telescopic subsystem magnet may be an electromagnetic quadrupole magnet 510, as shown in FIG. 5A. In some examples, the telescopic subsystem magnet may be a permanent quadrupole magnet 520, as shown in FIG. 5B. In some examples, the telescopic subsystem may comprise a plurality of quadrupole magnets. In some examples, the telescopic subsystem may have four quadrupole magnets. In some examples, the telescopic subsystem may comprise two or more magnetic quadrupoles. In some examples, the telescopic subsystem may comprise magnetic solenoid. In some examples, the telescopic subsystem may comprise a plurality of magnetic solenoids (e.g., one magnetic solenoid, one or more magnetic solenoids, two or more magnetic solenoids, three or more magnetic solenoids). In some examples, the one or more magnetic solenoids may be fixed. In some examples, the one or more magnetic solenoids may be adjustable.

The telescopic subsystem may comprise a plurality of magnetic quadrupoles (e.g., at least one electromagnetic quadrupole magnet, at least two electromagnetic quadrupole magnets, at least three electromagnetic quadrupole magnets, at least four electromagnetic quadrupole magnets). In some examples, the plurality of magnetic quadrupoles may comprise at least one permanent quadrupole magnet. In some examples, the plurality of magnetic quadrupoles may comprise at least two permanent quadrupole magnets. In some examples, the plurality of magnetic quadrupoles may comprise at least three permanent quadrupole magnets. In some examples, the plurality of magnetic quadrupoles may comprise at least four permanent quadrupole magnets. In some examples, the plurality of magnetic quadrupoles may comprise a combination of permanent quadrupole magnets and electromagnetic quadrupole magnets.

The plurality of magnetic quadrupoles may have a distance between at least two of the magnetic quadrupoles. In some examples, the distance between at least two magnetic quadrupoles may be equal to the distance between at least two other magnetic quadrupoles. For example, the distance between the first and second magnet quadrupoles may be equal to the distance between the third and fourth magnetic quadrupoles, etc. In some examples, the distance between at least two of the plurality of magnetic quadrupoles may be equal. In some examples, the distance between at least two of the plurality of magnetic quadrupoles may be unequal. The distance between at least two of the magnetic quadrupoles may be from about 1 cm to about 1000 cm, including from about 1 cm to about 10 cm, from about 10 cm to about 20 cm, from about 20 cm to about 30 cm, from about 30 cm to about 40 cm, from about 40 cm to about 50 cm, from about 50 cm to about 100 cm, from about 100 cm to about 250 cm, from about 250 cm to about 500 cm, from about 500 cm to about 750 cm, or from about 750 cm to about 1000 cm. In some cases, the distance between at least two of the magnetic quadrupoles may be about 5 cm, 10 cm, about 15 cm, about 20 cm, about 25 cm, about 30 cm, about 35 cm, about 40 cm, about 45 cm, about 50 cm, about 100 cm, or about 200 cm.

The plurality of magnetic quadrupoles may comprise at least one electromagnetic quadrupole magnet. In some examples, the at least one electromagnetic quadrupole magnet may be spaced apart. In some examples, the at least one electromagnetic quadrupole magnet may have a center to center spacing. The center to center spacing may be from about 1 cm to about 200 cm, such as from about 1 cm to about 10 cm, about 10 cm to about 50 cm, about 50 cm to about 100 cm, about 100 cm to about 150 cm, or about 150 cm to about 200 cm. In some examples, the center to center spacing may be about 1 cm, about 5 cm, about 10 cm, about 15 cm, about 20 cm, about 25 cm, about 30 cm, about 35 cm, about 40 cm, about 45 cm, or about 50 cm.

The at least one electromagnetic quadrupole magnets may have an iron yoke length. In some examples, the iron yoke length may be from about 1 cm to about 200 cm. In some cases, the iron yoke length may be from about 1 cm to about 10 cm, about 10 cm to about 50 cm, about 50 cm to about 100 cm, about 100 cm to about 150 cm, or about 150 cm to about 200 cm. In some examples, the iron yoke length may be about 1 cm, about 5 cm, about 10 cm, about 15 cm, about 20 cm, about 25 cm, about 30 cm, about 35 cm, about 40 cm, about 45 cm, or about 50 cm.

The at least one electromagnetic quadrupole magnets may have a bore size. In some examples, the bore size may be from 0.1 cm to about 5 cm, such as from 0.1 cm to about 1 cm or from 1 cm to about 5 cm. In some examples, the bore size may be about 0.7 cm. In some examples, the bore size may be about 1 cm. In some examples, the bore size may be about 2 cm. In some examples, the bore size may be about 3 cm. In some examples, the bore size may be about 4 cm. In some examples, the bore size may be about 5 cm.

The plurality of magnetic quadrupoles may comprise at least one permanent quadrupole magnet. In some examples, at least one permanent quadrupole magnet may be spaced apart. In some examples, at least one permanent quadrupole magnet may have a center to center spacing. In some examples, the center to center spacing may be from about 1 cm to about 200 cm. In some examples, the center to center spacing may be from about 1 cm to about 10 cm. In some examples, the center to center spacing may be from about 10 cm to about 50 cm. In some examples, the center to center spacing may be from about 50 cm to about 100 cm. In some examples, the center to center spacing may be from about 100 cm to about 150 cm. In some examples, the center to center spacing may be from about 150 cm to about 200 cm. In some examples, the center to center spacing may be about 1 cm. In some examples, the center to center spacing may be about 5 cm. In some examples, the center to center spacing may be about 10 cm. In some examples, the center to center spacing may be about 15 cm. In some examples, the center to center spacing may be about 20 cm. In some examples, the center to center spacing may be about 25 cm. In some examples, the center to center spacing may be about 30 cm. In some examples, the center to center spacing may be about 35 cm. In some examples, the center to center spacing may be about 40 cm. In some examples, the center to center spacing may be about 45 cm. In some examples, the center to center spacing may be about 50 cm.

The at least one permanent quadrupole magnets may have a length. In some examples, the length may be from about 1 cm to about 200 cm, including from about 1 cm to about 10 cm, from about 10 cm to about 50 cm, from about 50 cm to about 100 cm, from about 100 cm to about 150 cm, from about 150 cm to about 200 cm, about 1 cm, about 5 cm, about 10 cm, about 15 cm, about 20 cm, about 25 cm, about 30 cm, about 35 cm, about 40 cm, about 45 cm, or about 50 cm.

The at least one permanent quadrupole magnets may have a bore size. In some examples, the bore size may be from 0.1 cm to about 5 cm. In some examples, the bore size may be from 0.1 cm to about 1 cm. In some examples, the bore size may be from 1 cm to about 5 cm. In some examples, the bore size may be about 0.5 cm. In some examples, the bore size may be about 0.7 cm. In some examples, the bore size may be about 1 cm. In some examples, the bore size may be about 2 cm. In some examples, the bore size may be about 3 cm. In some examples, the bore size may be about 4 cm. In some examples, the bore size may be about 5 cm. In some examples, the telescopic subsystem may be adjusted. In some examples, the telescopic subsystem magnets may be adjusted. In some examples, the telescopic subsystem magnetic solenoids may be adjusted. In some examples, the telescopic subsystem magnetic quadrupoles may be adjusted. In some examples, the telescopic subsystem magnets may be adjusted in relation to one another. In some examples, the magnet positions may be adjusted. In some examples, the magnet positions along the axis of propagation may be adjusted.

The telescopic subsystem may comprise two or more magnets. In some examples, the telescopic subsystem may comprise two or more magnetic dipoles. In some examples, the telescopic subsystem may comprise two or more magnetic quadrupoles. In some examples, the telescopic subsystem may comprise two or more adjustable magnetic quadrupoles. In some examples, the two or more magnetic quadrupoles may be adjusted along the axis of propagation. In some examples, the two or more magnetic quadrupoles are present before the sample area. In some examples, at least one of the two or more magnetic quadrupoles are positioned within the sample area. In some examples, at least two of the two or more magnetic quadrupoles are positioned within the sample area. In some examples, the two or more magnetic quadrupoles are positioned within the sample area.

The system may comprise a sample area. In some examples, the sample area may further comprise a device under test. In some examples, the device under test may be an electronics unit. In some examples, the device under test may be a biological unit. In some examples, the device under test may be a structural unit. In some examples, the sample area may be a subject or patient. A subject or a patient may comprise an animal (e.g., birds, reptiles, and mammals), a mammal including a primate (e.g., a monkey, chimpanzee, and a human) and a non-primate (e.g., a camel, donkey, zebra, cow, pig, horse, cat, dog, rat, and mouse).

In some examples, the sample area may further comprise a sample chamber. In some examples, the device under test may be present within the sample chamber.

The virtual source may be projected onto the sample area. The virtual source may be projected downstream onto the sample chamber or onto the device under test. In some examples, the demagnified image of the virtual source may reside in the sample chamber. In some examples, the demagnified image of the virtual source may reside in the volume of the sample chamber.

The demagnified image of the virtual source in the sample chamber may have a transverse size. In some examples, the transverse size may be from about 0.01 micron to about 1000 microns, such as from about 0.1 micron to about 1 micron, from about 1 micron to about 10 microns, from about 10 microns to about 100 microns, from about 100 microns to about 500 microns, from about 500 microns to about 1000 microns, about 1 micron, about 10 microns, or greater than about of 10 microns. The transverse size may be less than 1 micron, less than 10 microns, less than 100 microns, or less than 1000 microns.

The demagnified image of the virtual source in the sample chamber may have a longitudinal size. The longitudinal size may be from about 1 femtosecond to about 10,000 femtoseconds, which may be from about 1 femtosecond to about 10 femtoseconds, about 10 femtosecond to about 100 femtoseconds, about 100 femtosecond to about 250 femtoseconds, about 250 femtosecond to about 500 femtoseconds, about 500 femtosecond to about 1,000 femtoseconds, about 1,000 femtosecond to about 2,000 femtoseconds, about 2,000 femtosecond to about 5,000 femtoseconds, about 5,000 femtosecond to about 10,000 femtoseconds, about 100 femtoseconds, about 2,000 femtoseconds, or greater than about 2,000 femtoseconds.

The sample chamber may further comprise a detector. In some examples, the sample chamber may comprise a silicon-based detector. In some examples, the sample chamber may comprise a silicon-based detector configured to provide transverse position measurements. In some examples, the sample chamber may comprise a silicon-based detector configured to provide transverse beam size measurements. In some examples, the sample chamber may comprise a silicon-based detector configured to provide charge measurements.

The sample chamber may further comprise an amplifier, such as a laser amplifier, a solid-state amplifier, a fiber amplifier, a doped-fiber amplifier, an erbium-doped optical fiber amplifier, a doped fiber amplifier, a semiconductor optical amplifier, a tapered amplifier, a Raman amplifier, an optical parametric amplifier, or a diamond amplifier.

The amplifier may be positioned in relation to the device under test. In some examples, the amplifier may be abutting the device under test. In some examples, the amplifier may be displaced from the device under test. In some examples, the amplifier may be crossed. In some examples, the amplifier may be a biased grid. In some examples, the amplifier may be configured to interact with the electron bunch. In some examples, the amplifier may be configured to profile the electron bunch. In some examples, the amplifier may be configured to sense the position of the electron bunch.

The sample area may further comprise a particle catch. In some examples, the particle catch may be charged. In some examples, the particle catch may be uncharged. In some examples, the particle catch may be calibrated. In some examples, the particle catch may be uncalibrated. In some examples, the particle catch may be a Faraday cup. In some examples, the particle catch may comprise a metal material. In some examples, the particle catch may comprise a non-metal material. In some examples, the particle catch may comprise stainless steel. In some examples, the particle catch may comprise tantalum. In some examples, the particle catch may comprise ceramic. In some examples, the particle catch may comprise polyimide. In some examples, the particle catch may comprise vacuum grade polyimide. In some examples, the particle catch may comprise brass.

### Dispersive Element

The system may comprise a dispersive element. In some examples, the system may comprise a plurality of dispersive elements. In some cases, the system may comprise one dispersive element, two dispersive elements, three dispersive elements, four dispersive elements, more than one dispersive element, more than two dispersive elements, more than three dispersive elements, or more than four dispersive elements. In some examples, the plurality of dispersive elements may be positioned along an axis. In some examples, the plurality of dispersive elements may be positioned along a plurality of axes. In some examples, the plurality of dispersive elements may be positioned along the axis of propagation. In some examples, at least one of the plurality of dispersive elements may be positioned before the first aperture. In some examples, at least one of the plurality of dispersive elements may be positioned after the first aperture.

The plurality of dispersive elements may be two dispersive elements. In some examples, the two dispersive elements may comprise a first dispersive element and second dispersive element. In some examples, the first dispersive element may be positioned before the first aperture or after the first aperture. In some examples, the second dispersive element may be positioned before the first aperture or after the first aperture.

The dispersive element may comprise a magnet. In some examples, the dispersive element may comprise a plurality of magnets. In some examples, the dispersive element may comprise one magnet. In some examples, the dispersive element may comprise two magnets. In some examples, the dispersive element may comprise three magnets. In some examples, the dispersive element may comprise four magnets. In some examples, the dispersive element may comprise more than four magnets. In some examples, the magnet may be a dipole. In some examples, the dispersive element may have one dipole magnets. In some examples, the dispersive element may have two dipole magnets. In some examples, the dispersive element may have four dipole magnets. In some examples, the magnet may be a quadrupole. In some examples, the dispersive element may have one quadrupole magnet. In some examples, the dispersive element may have two quadrupole magnets. In some examples, the dispersive element may have four quadrupole magnets. In some examples, the dispersive element may have one sextupole magnet. In some examples, the dispersive element may have two sextupole magnets. In some examples, the dispersive element may have four sextupole magnets.

The system may comprise two dispersive elements. In some examples, the two dispersive elements may comprise a first dispersive element and second dispersive element. In some examples, the first dispersive element may comprise a plurality of dipoles. In some examples, the first dispersive element may comprise two dipoles. In some examples, the first dispersive element may comprise a first dipole and a second dipole. In some examples, the second dispersive element may comprise a plurality of dipoles. In some examples, the second dispersive element may comprise two dipoles. In some examples, the second dispersive element may comprise a third dipole and a fourth dipole.

The plurality of dipoles may have a distance between two of the dipoles. In some examples, the distance between at least two dipoles may be equal to the distance between at least two other dipoles. For example, the distance between the first and second dipoles may be equal to the distance between the third and fourth dipoles, etc. In some examples, the distance between two of the plurality of dipoles may be equal. In some examples, the distance between two of the plurality of dipoles may be unequal. The distance between at least two of the dipoles may be from about 10 cm to about 1000 cm, such as from about 10 cm to about 20 cm, from about 20 cm to about 30 cm, from about 30 cm to about 40 cm, from about 40 cm to about 50 cm, from about 50 cm to about 100 cm, from about 100 cm to about 250 cm, from about 250 cm to about 500 cm, from about 500 cm to about 750 cm, from about 750 cm to about 1000 cm, about 50 cm, about 100 cm, about 150 cm, about 200 cm, about 250 cm, about 300 cm, about 350 cm, about 400 cm, about 450 cm, about 500 cm, about 600 cm, about 700 cm, about 800 cm, about 900 cm, or about 1000 cm.

The dispersive element may comprise a plurality of dipoles. In some examples, the plurality of dipoles are unique. In some examples, at least one dipole of the plurality of dipoles is unique. In some examples, the plurality of dipoles are identical.

A dipole of the plurality of dipoles may have an effective length. In some examples, the effective length may be from about 1 cm to about 200 cm, which may include from about 1 cm to about 20 cm, from about 20 cm to about 40 cm, from about 40 cm to about 60 cm, from about 60 cm to about 80 cm, from about 80 cm to about 100 cm, from about 100 cm to about 200 cm, about 1 cm, about 5 cm, about 10 cm, about 15 cm, or about 20 cm. In some examples, the effective length is 10 cm.

A dipole of the plurality of dipoles may have a thickness, where the thickness is the longitudinal length of the dipole colinear to the axis of propagation. The dipole length may be from about 10 cm to about 300 cm, which may be from about 10 cm to about 100 cm, from about 100 cm to about 200 cm, or from about 200 cm to about 300 cm. In some examples, the dipole length may be about 20 cm.

The dispersive element may be designed to shift the particle beam. In some examples, the dispersive element may be designed to shift the direction of the particle beam. In some examples, the dispersive element may be designed to shift the particle beam to an axis not colinear to the particle beam entry axis. In some examples, the dispersive element may be designed to bend the particle beam at an angle from the particle beam entry axis. In some examples, the dispersive element may bend the particle beam back to the particle beam entry axis. In some examples, the dispersive element may not bend the particle beam back to the particle beam entry axis.

The dispersive element may bend the particle beam at an angle. The angle may be from about 1 mrad (milliradian) to about 200 mrad, where the angle may be from about 1 mrad to 25 mrad, about 25 mrad to about 50 mrad, about 50 mrad to about 75 mrad, about 75 mrad to about 100 mrad, about 100 mrad to about 200 mrad, about 10 mrad, about 20 mrad, about 25 mrad, about 30 mrad, about 35 mrad, about 40 mrad, or about 50 mrad. In some examples, the angle may be 35 mrad.

The dispersive element may be configured to separate the particle beam from the laser beam. In some examples, the dispersive element may be configured to completely separate the particle beam from the laser. In some examples, the dispersive element may be configured to partially separate the particle beam from the laser. In some examples, the dispersive element may be configured to remove from about 0% to about 25% of the particle beam from the laser beam. In some examples, the dispersive element may be configured to remove from about 25% to about 50% of the particle beam from the laser beam. In some examples, the dispersive element may be configured to remove from about 50% to about 75% of the particle beam from the laser beam. In some examples, the dispersive element may be configured to remove from about 75% to about 100% of the particle beam from the laser beam. In some examples, the dispersive element may be configured to completely separate the particle beam from the laser beam. In some examples, the dispersive element may remove remaining laser power. In some examples, the dispersive element may remove remaining particle beam power.

The dispersive element may be configured to achieve dispersion. The dispersion may be chromatic dispersion. The dispersive element may achieve dispersion such that a Gaussian width of the energy of the particle beam spans a distance around 0 between from about −20 cm to about 20 cm, which is inclusive of from about −1 cm to about 1 cm, about −2 cm to about 2 cm, about −5 cm to about 5 cm, about −10 cm to about 10 cm, or about −20 cm to about 20 cm. In some examples, the dispersive element may achieve dispersion about 10 cm.

The dispersive element may define the electron beam energy. In some examples, the dispersive element may define the residual energy spread. In some examples, the dispersive element may reduce the particle beam energy deviation. In some examples, the dispersive element may reduce the particle beam energy deviation compared to the particle beam energy deviation upon introduction to the dispersive element. In some examples, the dispersive element may reduce the particle beam residual energy spread compared to the particle beam residual energy spread before introduction to the dispersive element.

The dispersive element may be configured to reduce the particle beam energy variation. In some examples, the dispersive element may be configured to reduce the particle beam energy variation from about 0.01% to about 5%. In some examples, the dispersive element may be configured to reduce the particle beam energy variation from about 0.01% to about 0.1%. In some examples, the dispersive element may be configured to reduce the particle beam energy variation from about 0.1% to about 0.5%. In some examples, the dispersive element may be configured to reduce the particle beam energy variation from about 0.5% to about 1%. In some examples, the dispersive element may be configured to reduce the particle beam energy variation from about 1% to about 2%. In some examples, the dispersive element may be configured to reduce the particle beam energy variation from about 2% to about 3%. In some examples, the dispersive element may be configured to reduce the particle beam energy variation from about 3% to about 4%. In some examples, the dispersive element may be configured to reduce the particle beam energy variation from about 4% to about 5%. In some examples, the dispersive element may be configured to reduce the particle beam energy variation by greater than about 0.01%. In some examples, the dispersive element may be configured to reduce the particle beam energy variation by greater than about 0.1%. In some examples, the dispersive element may be configured to reduce the particle beam energy variation by greater than about 0.2%. In some examples, the dispersive element may be configured to reduce the particle beam energy variation by greater than about 0.3%. In some examples, the dispersive element may be configured to reduce the particle beam energy variation by greater than about 0.4%. In some examples, the dispersive element may be configured to reduce the particle beam energy variation by greater than about 0.5%. In some examples, the dispersive element may be configured to reduce the particle beam energy variation by greater than about 0.6%. In some examples, the dispersive element may be configured to reduce the particle beam energy variation by greater than about 0.7%. In some examples, the dispersive element may be configured to reduce the particle beam energy variation by greater than about 0.8%. In some examples, the dispersive element may be configured to reduce the particle beam energy variation by greater than about 0.9%. In some examples, the dispersive element may be configured to reduce the particle beam energy variation by greater than about 1%. In some examples, the dispersive element may be configured to reduce the particle beam energy variation by greater than about 2%. In some examples, the dispersive element may be configured to reduce the particle beam energy variation by greater than about 3%. In some examples, the dispersive element may be configured to reduce the particle beam energy variation by greater than about 4%. In some examples, the dispersive element may be configured to reduce the particle beam energy variation by greater than about 5%.

The dispersive element may be configured to reduce the particle beam energy. In some examples, the dispersive element may be configured to reduce the particle beam energy variation. In some examples, the dispersive element may be configured to reduce the particle beam energy variation to less than 50%, less than 25%, less than 10%, less than 5%, less than 1%, less than 0.1%, or less than 0.01%.

The dispersive element may further comprise a beam stripper plate. In some examples, the beam stripper plate may be an opaque surface. In some examples, the beam stripper plate may be a metal plate. In some examples, the plate may comprise a plurality of metals. In some examples, the plate may comprise a single metal. In some examples, the plate may comprise a metal selected from the group comprising of Li, Be, Mg, Al, Ca, Sc, Ti, V, Cr, Mn, Fe, Co, Ni, Cu, Zn, Ga, Sr, Y, Zr, Nb, Mo, Tc, Ru, Rh, Pd, Ag, Cd, In, Sn, Ba, Hf, Ta, W, Re, Os, Ir, Pt, Au, Hg, Tl, Pb, Bi, La, Ce, Pr, Nd, Pm, Sm, Eu, Gd, Tb, Dy, Ho, Er, Tm, Yb, and combinations thereof. In some examples, the plate may comprise tungsten (W). In some examples, the beam stripper plate may be a non-metal surface. In some examples, the beam stripper plate may be a transparent surface. In some examples, the beam stripper plate may be a glass surface. In some examples, the beam stripper plate may be a reflective surface. In some examples, the beam stripper plate may be a mirror. In some examples, the beam stripper plate may be configured to act as a beam stop. In some examples, the beam stripper plate may be configured to remove a portion of the particle beam. In some examples, the beam stripper plate may be configured to remove a high energy portion of the particle beam. In some examples, the beam stripper plate may be configured to remove a low energy portion of the particle beam.

The beam stripper plate may be adjustable. In some examples, the beam stripper plate size may be adjustable. In some examples, the beam stripper plate thickness may be adjustable. In some examples, the beam stripper plate position may be adjustable. In some examples, the beam stripper plate may be translatable along the axis of propagation. In some examples, the beam stripper plate may be translatable along an axis not colinear with the axis of propagation. In some examples, the beam stripper plate may be longitudinally translatable. In some examples, the beam stripper plate may be transversely translatable.

### Second Aperture

The particle beam may interact with a second aperture. In some cases, the second aperture may be positioned along the axis of propagation, in relation to the first aperture, before the first aperture, after the first aperture, or before the first aperture along the axis of propagation.

In some examples, the second aperture may have a shape (e.g., a triangle, a square, a rectangle, a pentagon, a circle, a hole). In some examples, the second aperture may be any suitable shape.

The second aperture may have a diameter. In some examples, the diameter may be from around 10 μm (micrometer) to about 10 mm (millimeter). In some examples, the diameter may be from about 10 μm to about 100 μm. In some examples, the diameter may be from about 100 μm to about 1 mm. In some examples, the diameter may be from about 1 mm to about 10 mm. In some examples, the diameter may be about 10 μm. In some examples, the diameter may be about 100 μm. In some examples, the diameter may be about 1 mm. In some examples, the diameter may be about 10 mm. In some examples, the diameter may be about 100 μm.

The second aperture may be positioned on a surface. In some examples, the surface may be an opaque surface. In some examples, the surface may be a metal plate. In some examples, the plate may comprise a plurality of metals. In some examples, the plate may comprise a single metal. In some examples, the plate may comprise a metal selected from the group comprising Li, Be, Mg, Al, Ca, Sc, Ti, V, Cr, Mn, Fe, Co, Ni, Cu, Zn, Ga, Sr, Y, Zr, Nb, Mo, Tc, Ru, Rh, Pd, Ag, Cd, In, Sn, Ba, Hf, Ta, W, Re, Os, Ir, Pt, Au, Hg, Tl, Pb, Bi, La, Ce, Pr, Nd, Pm, Sm, Eu, Gd, Tb, Dy, Ho, Er, Tm, Yb, and combinations thereof. In some examples, the plate may comprise tungsten (W). In some examples, the surface may be a non-metal surface. In some examples, the surface may be a transparent surface. In some examples, the surface may be a glass surface. In some examples, the surface may be a reflective surface. In some examples, the surface may be a mirror. In some examples, the mirror is a plane mirror. In some examples, the mirror is a convex mirror. In some examples, the mirror is a concave mirror. In some examples, the mirror is flat. In some examples, the mirror may further comprise an aperture. In some examples, the mirror may comprise a plurality of apertures. In some examples, the aperture may be centrally positioned on the mirror. In some examples, the aperture may not be centrally positioned on the mirror. In some examples, the surface may be configured to act as a beam stop.

The second aperture may be configured to provide diagnostic capabilities. In some examples, the second aperture may be configured to stabilize the particle beam energy. In some examples, the second aperture may be configured to stabilize a portion of the particle beam energy. In some examples, the second aperture may be configured to stabilize the particle beam energy spread. In some examples, the second aperture may be configured to remove particle beam power. In some examples, the second aperture may remove a percentage of the particle beam power. In some examples, the second aperture may remove a low amount of particle beam power. In some examples, the second aperture may remove from about 1% to about 50% of the particle beam power. In some examples, the second aperture may remove about 1% to about 25% of the particle beam power. In some examples, the second aperture may remove about 25% to about 50% of the particle beam power. In some examples, the second aperture may remove a high amount of particle beam power. In some examples, the second aperture may remove from about 50% to about 99% of the particle beam power. In some examples, the second aperture may remove from about 50% to about 75% of the particle beam power. In some examples, the second aperture may remove from about 75% to about 99% of the particle beam power. In some examples, the second aperture may remove more than about 50% of the particle beam power.

The particle beam may pass through the second aperture without interference. In some examples, the particle beam may pass through the second aperture with interference. In some examples, the second aperture may allow from about 0% to about 25% of the particle beam to pass through. In some examples, the second aperture may allow from about 25% to about 50% of the particle beam to pass through. In some examples, the second aperture may allow from about 50% to about 75% of the particle beam to pass through. In some examples, the second aperture may allow from about 75% to about 100% of the particle beam to pass through.

The second aperture may stabilize the beam transverse pointing jitter. In some examples, the beam jitter may be angular beam jitter. The second aperture may stabilize the angular beam jitter from about 10 microradians to about 10 milliradians, such as from about 10 microradians to about 100 microradians, about 100 microradians to about 1 milliradian, about 1 milliradian to about 2.5 milliradians, about 2.5 milliradians to about 5 milliradians, about 5 milliradians to about 7.5 milliradians, or about 7.5 milliradians to about 10 milliradians.

The second aperture may stabilize the beam transverse pointing jitter. In some examples, the beam jitter may be positional beam jitter. The second aperture may stabilize the positional beam jitter from about 10 microns to about 1 millimeter (e.g., greater than 10 microns, greater than about 100 microns, greater than about 1 millimeter, from about 10 microns to about 100 microns, from about 100 microns to about 250 microns, from about 250 microns to about 500 microns, from about 500 microns to about 750 microns, from about 750 microns to about 1 millimeter).

The second aperture may create particle beam fragments. In some examples, the second aperture may create one beam fragment. In some examples, the second aperture may create two beam fragments. In some examples, the second aperture may create three beam fragments. In some examples, the second aperture may create four beam fragments. In some examples, the second aperture may create more than two beam fragments. In some examples, the second aperture may create more than three beam fragments. In some examples, the second aperture may create more than four beam fragments. In some examples, the second aperture may create a beam fragment array. In some examples, the second aperture may create a plurality of beam fragments. In some examples, the plurality of beam fragments may include a first beam fragment and a second beam fragment. In some examples, at least one of the plurality of beam fragments may pass through the second aperture. In some examples, at least one of the plurality of beam fragments may interact with the aperture surface. In some examples, at least one of the plurality of beam fragments may be absorbed by the aperture surface. In some examples, the first beam fragment may interact with the aperture surface. In some examples, the first beam fragment may be absorbed by the aperture surface. In some examples, the second beam fragment may pass through the second aperture. In some examples, the second beam fragment may interact with the aperture surface. In some examples, the second beam fragment may be absorbed by the aperture surface.

A second mirror, further downstream of the first mirror, may be present. In some cases, the second mirror may be positioned before the dispersive element, after the dispersive element, or within the plurality of magnets making up the dispersive element. In some examples, the second mirror may be configured to remove laser power, extract residual laser power, or extract residual laser power that has been separated from the particle beam due to the dispersive element.

The system may comprise an integrating current transformer (ICT). In some examples, the integrating current transformer may be calibrated. In some examples, the integrating current transformer may not be calibrated. In some examples, the integrating current transformer may be a passive current transformer. In some examples, the integrating current transformer may be active. In some examples, the integrating current transformer may measure charges. In some examples, the integrating current transformer may measure the charge of the electron beam.

The system may further comprise an electron beam diffuser, or attenuator. In some examples, the diffuser may be a stepped diffuser. In some examples, the diffuser may be configured to control beam homogeneity. In some examples, the diffuser may be configured to control the delivered charge. In some examples, the diffuser may be positioned upstream of the aperture. In some examples, the diffuser may be positioned downstream of the pinhole. In some examples, the diffuser is a stepped diffuser upstream of the pinhole.

The diffuser may comprise a diffuser material. In some examples, the diffuser material may be a metal. In some examples, the diffuser material may comprise a plurality of metals. In some examples, the diffuser material may comprise a single metal. In some examples, the diffuser material may comprise a metal selected from the group comprising of Li, Be, Mg, Al, Ca, Sc, Ti, V, Cr, Mn, Fe, Co, Ni, Cu, Zn, Ga, Sr, Y, Zr, Nb, Mo, Tc, Ru, Rh, Pd, Ag, Cd, In, Sn, Ba, Hf, Ta, W, Re, Os, Ir, Pt, Au, Hg, Tl, Pb, Bi, La, Ce, Pr, Nd, Pm, Sm, Eu, Gd, Tb, Dy, Ho, Er, Tm, Yb, and combinations thereof. In some examples, the diffuser material may comprise tungsten (W). In some examples, the diffuser material may be a non-metal. In some examples, the diffuser material may be ceramic.

The system may further comprise a beam stop. In some examples, the beam stop may be positioned along the axis of propagation. In some examples, the beam stop may be positioned after the sample area along the axis of propagation. In some examples, the beam stop may be positioned abutting to the sample area. In some examples, the beam stop may comprise a beam stop material. In some examples, the beam stop material may be an absorptive material. In some examples, the beam stop material may be resistant to laser damage. In some examples, the beam stop material may be resistant to thermal stress. In some examples, the beam stop material may be resistant to a high level of laser damage. In some examples, the beam stop material may be resistant to a high level of thermal stress. In some examples, the beam stop material may be a carbide. In some examples, the beam stop material may be a ceramic. In some examples, the beam stop material may be a metal. In some examples, the beam stop material may be an alloy. In some examples, the alloys may comprise any suitable metal, including, but not limited to, Ag, Al, Au, Bi, C, Cr, Cu, Fe, Mg, Mn, Ni, Pb, Sb, Sn, and Zn. In some examples, the beam stop material may be steel. In some examples, the beam stop material may be graphite. In some examples, the beam stop material may be molybdenum. In some examples, the beam stop material may be tungsten. In some examples, the beam stop material may be concrete. In some examples, the beam stop material may be marble. In some examples, the beam stop material may be cast-iron shielding. In some examples, the beam stop material may be aluminum. In some examples, the beam stop material may be anodized aluminum. In some examples, the beam stop material may be silicon carbide. In some examples, the beam stop material may be a combination thereof.

### Methods of Use

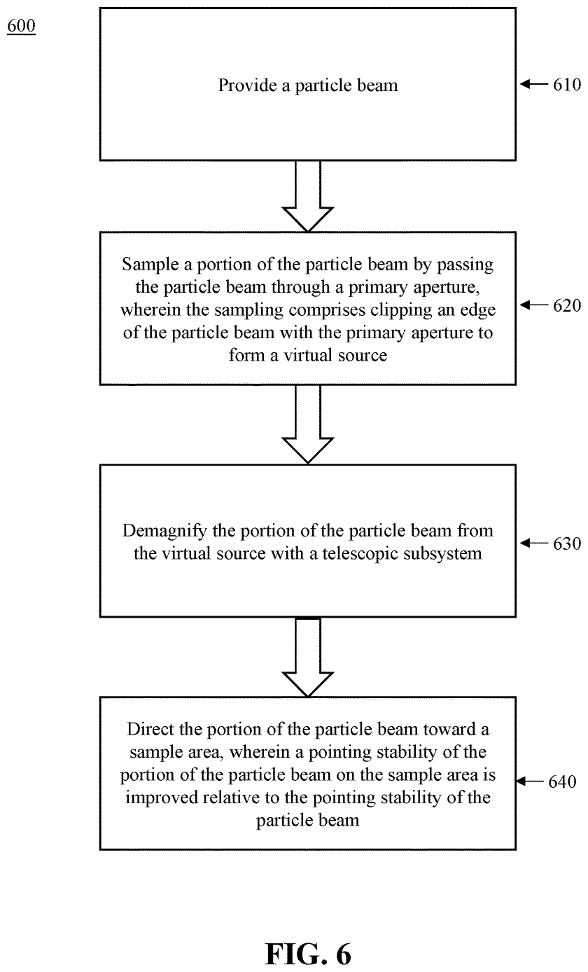

Also disclosed herein are methods 600 for stabilizing a particle beam, such as that in FIG. 6. In some examples, the method may comprise (a) providing a particle beam 610; (b) sampling a portion of the particle beam by passing the particle beam through a first aperture, wherein the sampling comprises clipping an edge of the particle beam with the first aperture to form a virtual source 620; (c) demagnifying the portion of the particle beam from the virtual source with a telescopic subsystem 630; and (d) directing the portion of the particle beam toward a sample area, wherein a pointing stability of the portion of the particle beam on the sample area is improved relative to the pointing stability of the original particle beam 640.

The particle beam in (a) 610 may have an energy. In some examples, the particle beam in (a) may be high energy. In some cases, the high energy electron beam may have an energy greater than about 1 MeV, greater than about 5 MeV, greater than about 10 MeV, greater than about 50 MeV, greater than about 100 MeV, greater than about 150 MeV, greater than about 200 MeV, greater than about 250 MeV, greater than about 500 MeV, greater than about 1000 MeV, greater than 5 GeV, greater than 10 GeV, greater than 50 GeV, greater than 100 GeV. In some cases, the energy may be from about 1 MeV to about 1000 MeV, from about 1 MeV to about 50 MeV, from about 50 MeV to about 100 MeV, from about 100 MeV to about 150 MeV, from about 150 MeV to about 200 MeV, from about 200 MeV to about 250 MeV, from about 250 MeV to about 500 MeV, from about 500 MeV to about 750 MeV, from about 750 MeV to about 1000 MeV, from about 1000 MeV to about 10 GeV, or from about 10 GeV to about 100 GeV. In some examples, the energy may be greater than about 5 MeV.

The particle beam in (a) 610 may have an energy. In some examples, the particle beam may have a minimum energy. In some cases, the minimum energy may be greater than about 50 MeV, greater than about 100 MeV, greater than about 150 MeV, greater than about 200 MeV, greater than about 250 MeV, greater than about 500 MeV, greater than about 1000 MeV, or greater than about 1000 MeV.

The particle beam in (a) 610 may comprise a beam jitter. In some examples, the beam jitter may be angular beam jitter. In some examples, the particle beam jitter may be a deviation from the particle beam path. The particle beam jitter deviation may be greater than about 0.01 milliradian, greater than about 0.1 milliradian, greater than about 1 milliradian, greater than about 10 milliradians. In some examples, the particle beam jitter deviation may be from about 0.01 milliradian to about 0.1 milliradian, from about 0.1 milliradian to about 1 milliradian, from about 1 milliradian to about 2.5 milliradians, from about 2.5 milliradians to about 5 milliradians, from about 5 milliradians to about 7.5 milliradians, or from about 7.5 milliradians to about 10 milliradians.

The particle beam in (a) 610 may be generated from a particle beam source. In some examples, the particle beam source may be located along an axis of propagation. In some examples, the particle beam source may be located along a second axis different from the axis of propagation. In some examples, the particle beam source may be cathode-ray tubes. In some examples, the particle beam source may be an electron gun. In some examples, the particle beam source may be an ion source. In some examples, the particle beam source may further comprise a photocathode. In some examples, the particle beam source may further comprise a metallic photocathode. In some examples, the particle beam source may further comprise a high quantum efficiency photocathode. In some examples, the particle beam source may further comprise a thermionic cathode. In some examples, the particle beam source may further comprise a UV pulse. In some examples, the particle beam source may further comprise a visible pulse. In some examples, the particle beam source may be an accelerator system. In some examples, the particle beam source may be an RF accelerator system. In some examples, the particle beam source may be a particle accelerator. In some examples, the particle beam source may be a plasma accelerator. In some examples, the particle beam source may be a wakefield accelerator system. In some examples, the wakefield accelerator system may be driven by a laser. In some examples, the wakefield accelerator system may be driven by a particle beam. In some examples, the particle beam source may be a radiofrequency accelerator.

The method at (b) 620 may further comprise additional operations. In some examples, the method at (b) may further comprise (i) stabilizing a transverse beam jitter using the first aperture. In some examples, the method at (b) may further comprise (ii) forming the virtual source of the stabilized portion of the beam using a second aperture. In some examples, the method at (b) may further comprise (iii) stabilizing a beam energy and an energy spread of the portion of the beam using the second aperture.

The method may comprise sampling a portion of the particle beam 620. In some examples, the portion of the particle beam may be sampled from a central portion. In some example, the portion of the particle beam may be sampled from a non-central portion of the particle beam. In some examples, the portion of the particle beam may comprise a centroid energy. In some examples, the first aperture may select a centroid energy of the particle beam, wherein the centroid energy is equal to the virtual source energy. In some examples, the first aperture position may adjust the selected centroid energy, wherein the first aperture position may control the virtual source energy.

The position of the first aperture may select a centroid energy of the particle beam forming a portion of the particle beam. In some examples, the centroid energy may form the portion of the particle beam. The centroid energy may be greater than about 1 MeV, greater than about 5 MeV, greater than about 10 MeV, greater than about 15 MeV, greater than about 20 MeV, greater than about 25 MeV, greater than about 50 MeV, greater than about 100 MeV, greater than about 150 MeV, greater than about 200 MeV, greater than about 250 MeV, greater than about 500 MeV, or greater than about 1000 MeV. The centroid energy may be from about 5 MeV to about 1000 MeV, from about 5 MeV to about 25 MeV, from about 25 MeV to about 50 MeV, from about 50 MeV to about 100 MeV, from about 100 MeV to about 250 MeV, from about 250 MeV to about 500 MeV, or from about 500 MeV to about 1000 MeV. The method at (b) may further comprise clipping the edges of the particle beam by the first aperture. In some examples, the clipping of the particle beam may reduce the variation in the centroid energy of the particle beam from the virtual source. In some examples, the clipping of the particle beam may reduce the variation by a percentage. In some examples, the first aperture may be configured to reduce the particle beam energy variation from about 0.01% to about 5%. In some examples, the first aperture may be configured to reduce the particle beam energy variation from about 0.01% to about 0.1%. In some examples, the first aperture may be configured to reduce the particle beam energy variation from about 0.1% to about 0.5%. In some examples, the first aperture may be configured to reduce the particle beam energy variation from about 0.5% to about 1%. In some examples, the first aperture may be configured to reduce the particle beam energy variation from about 1% to about 2%. In some examples, the first aperture may be configured to reduce the particle beam energy variation from about 2% to about 3%. In some examples, the first aperture may be configured to reduce the particle beam energy variation from about 3% to about 4%. In some examples, the first aperture may be configured to reduce the particle beam energy variation from about 4% to about 5%. In some examples, the first aperture may be configured to reduce the particle beam energy variation by greater than about 0.1%. In some examples, the first aperture may be configured to reduce the particle beam energy variation by greater than about 0.2%. In some examples, the first aperture may be configured to reduce the particle beam energy variation by greater than about 0.3%. In some examples, the first aperture may be configured to reduce the particle beam energy variation by greater than about 0.4%. In some examples, the first aperture may be configured to reduce the particle beam energy variation by greater than about 0.5%. In some examples, the first aperture may be configured to reduce the particle beam energy variation by greater than about 0.6%. In some examples, the first aperture may be configured to reduce the particle beam energy variation by greater than about 0.7%. In some examples, the first aperture may be configured to reduce the particle beam energy variation by greater than about 0.8%. In some examples, the first aperture may be configured to reduce the particle beam energy variation by greater than about 0.9%. In some examples, the first aperture may be configured to reduce the particle beam energy variation by greater than about 1%. In some examples, the first aperture may be configured to reduce the particle beam energy variation by greater than about 2%. In some examples, the first aperture may be configured to reduce the particle beam energy variation by greater than about 3%. In some examples, the first aperture may be configured to reduce the particle beam energy variation by greater than about 4%. In some examples, the first aperture may be configured to reduce the particle beam energy variation by greater than about 5%.

The method may comprise demagnifying the portions of the particle beam from the virtual source with a telescopic subsystem 630.

The method may further comprise an improvement in the particle beam pointing stability 640. In some examples, the improvement in the particle beam pointing stability may improve by decreasing the particle beam jitter. In some examples, the particle beam jitter may be improved relative to the provided particle beam. In some examples, the particle beam jitter may be improved by a relative percentage. In some examples, the particle beam jitter may be relatively improved by about 50% to about 99.99%. In some examples, the particle beam jitter may be relatively improved by about 50% to about 60%. In some examples, the particle beam jitter may be relatively improved by about 60% to about 70%. In some examples, the particle beam jitter may be relatively improved by about 70% to about 80%. In some examples, the particle beam jitter may be relatively improved by about 80% to about 90%. In some examples, the particle beam jitter may be relatively improved by about 90% to about 99.99%. In some examples, the particle beam jitter may be relatively improved by about 50%. In some examples, the particle beam jitter may be relatively improved by about 55%. In some examples, the particle beam jitter may be relatively improved by about 60%. In some examples, the particle beam jitter may be relatively improved by about 65%. In some examples, the particle beam jitter may be relatively improved by about 70%. In some examples, the particle beam jitter may be relatively improved by about 75%. In some examples, the particle beam jitter may be relatively improved by about 80%. In some examples, the particle beam jitter may be relatively improved by about 85%. In some examples, the particle beam jitter may be relatively improved by about 90%. In some examples, the particle beam jitter may be relatively improved by about 95%. In some examples, the particle beam jitter may be relatively improved by about 99%.

The method may further comprise an improvement in the particle beam pointing stability 640. In some examples, the improvement in the particle beam pointing stability may improve by decreasing the particle beam jitter. In some examples, the particle beam jitter may be improved relative to the provided particle beam. In some examples, the particle beam jitter may be improved to no greater than from about 0.1 mrad to about 5 mrad. In some examples, the particle beam jitter may be improved to no greater than from about 0.1 mrad to about 0.5 mrad. In some examples, the particle beam jitter may be improved to no greater than from about 0.5 mrad to about 1 mrad. In some examples, the particle beam jitter may be improved to no greater than from about 1 mrad to about 2 mrad. In some examples, the particle beam jitter may be improved to no greater than from about 2 mrad to about 3 mrad. In some examples, the particle beam jitter may be improved to no greater than from about 3 mrad to about 4 mrad. In some examples, the particle beam jitter may be improved to no greater than from about 4 mrad to about 5 mrad. In some examples, the particle beam jitter may be improved to no greater than about 0.1 mrad. In some examples, the particle beam jitter may be improved to no greater than about 0.5 mrad. In some examples, the particle beam jitter may be improved to no greater than about 1 mrad. In some examples, the particle beam jitter may be improved to no greater than about 1.5 mrad. In some examples, the particle beam jitter may be improved to no greater than about 2 mrad. In some examples, the particle beam jitter may be improved to no greater than about 2.5 mrad. In some examples, the particle beam jitter may be improved to no greater than about 3 mrad. In some examples, the particle beam jitter may be improved to no greater than about 3.5 mrad. In some examples, the particle beam jitter may be improved to no greater than about 4 mrad. In some examples, the particle beam jitter may be improved to no greater than about 4.5 mrad. In some examples, the particle beam jitter may be improved to no greater than about 5 mrad. In some examples, the particle beam jitter may be improved to no greater than 0.5 mrad.

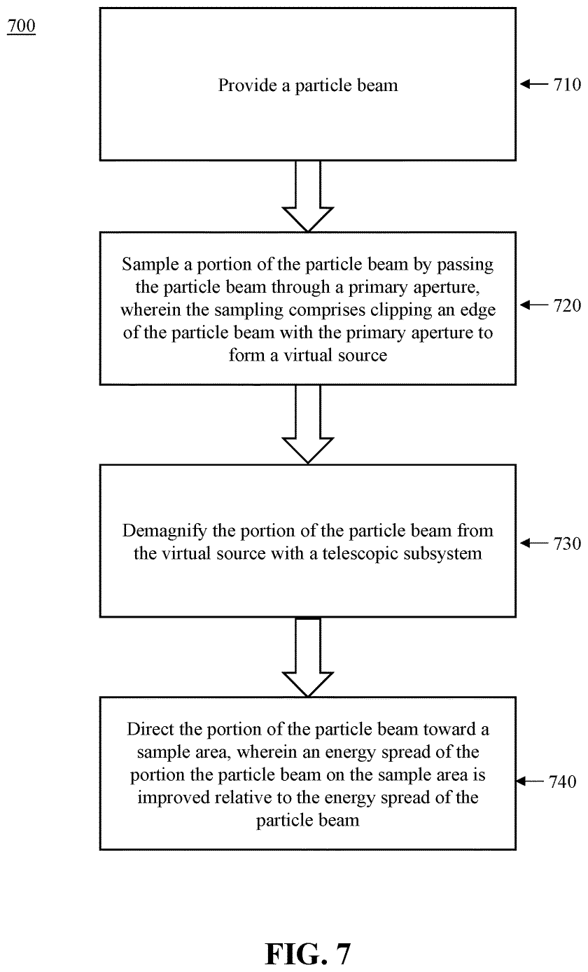

Also disclosed herein are methods 700 for stabilizing a particle beam, such as that in FIG. 7. In some examples, the method may comprise (a) providing a particle beam 710; (b) sampling a portion of the particle beam by passing the particle beam through a first aperture, wherein the sampling comprises clipping an edge of the particle beam with the first aperture to form a virtual source 720; (c) demagnifying the portion of the particle beam from the virtual source with a telescopic subsystem 730; and (d) directing the portion of the particle beam toward a sample area, wherein an energy spread of the portion of the particle beam on the sample area is improved relative to the energy spread of the original particle beam 740.

The particle beam in (a) 710 may have an energy. In some examples, the particle beam in (a) may be high energy. In some cases, the high energy electron beam may have an energy greater than about 1 MeV, greater than about 5 MeV, greater than about 10 MeV, greater than about 50 MeV, greater than about 100 MeV, greater than about 150 MeV, greater than about 200 MeV, greater than about 250 MeV, greater than about 500 MeV, greater than about 1000 MeV, greater than 5 GeV, greater than 10 GeV, greater than 50 GeV, greater than 100 GeV. In some cases, the energy may be from about 1 MeV to about 1000 MeV, from about 1 MeV to about 50 MeV, from about 50 MeV to about 100 MeV, from about 100 MeV to about 150 MeV, from about 150 MeV to about 200 MeV, from about 200 MeV to about 250 MeV, from about 250 MeV to about 500 MeV, from about 500 MeV to about 750 MeV, from about 750 MeV to about 1000 MeV, from about 1000 MeV to about 10 GeV, or from about 10 GeV to about 100 GeV. In some examples, the energy may be greater than about 1 GeV.

The particle beam in (a) 710 may have an energy. In some examples, the particle beam may have a minimum energy. In some cases, the minimum energy may be greater than about 50 MeV, greater than about 100 MeV, greater than about 150 MeV, greater than about 200 MeV, greater than about 250 MeV, greater than about 500 MeV, greater than about 1000 MeV, or greater than about 1000 MeV.

The particle beam in (a) 710 may have an energy spread. In some examples, the energy spread may be from around ±0.1 MeV to around ±100 MeV. In some examples, the energy spread may be from around ±1 MeV to around ±10 MeV. In some examples, the energy spread may be from around ±0.1 MeV to around ±10 MeV. In some examples, the energy spread may be from around ±10 MeV to around ±20 MeV. In some examples, the energy spread may be from around ±20 MeV to around ±30 MeV. In some examples, the energy spread may be from around ±30 MeV to around ±40 MeV. In some examples, the energy spread may be from around ±40 MeV to around ±50 MeV. In some examples, the energy spread may be from around ±50 MeV to around ±60 MeV. In some examples, the energy spread may be from around ±60 MeV to around ±70 MeV. In some examples, the energy spread may be from around ±70 MeV to around ±80 MeV. In some examples, the energy spread may be from around ±80 MeV to around ±90 MeV. In some examples, the energy spread may be from around ±90 MeV to around ±100 MeV. In some examples, the energy spread may be around ±1 MeV. In some examples, the energy spread may be around ±0.1 MeV. In some examples, the energy spread may be around ±5 MeV. In some examples, the energy spread may be around ±10 MeV. In some examples, the energy spread may be around ±20 MeV. In some examples, the energy spread may be around ±30 MeV. In some examples, the energy spread may be around ±40 MeV. In some examples, the energy spread may be around ±50 MeV. In some examples, the energy spread may be around ±60 MeV. In some examples, the energy spread may be around ±70 MeV. In some examples, the energy spread may be around ±80 MeV. In some examples, the energy spread may be around ±90 MeV. In some examples, the energy spread may be around ±100 MeV. In some examples, the energy spread may be ±10 MeV.

The particle beam in (a) 710 may be generated from a particle beam source. In some examples, the particle beam source may be located along an axis of propagation. In some examples, the particle beam source may be located along a second axis different from the axis of propagation. In some examples, the particle beam source may be cathode-ray tubes. In some examples, the particle beam source may be an electron gun. In some examples, the particle beam source may be an ion source. In some examples, the particle beam source may be a photocathode. In some examples, the particle beam source may be a thermionic source. In some examples, the particle beam source may be an accelerator system. In some examples, the particle beam source may be a particle accelerator. In some examples, the particle beam source may be a plasma accelerator. In some examples, the particle beam source may be a wakefield accelerator system. In some examples, the wakefield accelerator system may be driven by a laser. In some examples, the wakefield accelerator system may be driven by a particle beam. In some examples, the particle beam source may be a radiofrequency accelerator.

The method at (b) 720 may further comprise additional operations. In some examples, the method at (b) may further comprise (i) stabilizing a transverse beam jitter using the first aperture. In some examples, the method at (b) may further comprise (ii) forming the virtual source of the stabilized portion of the beam using a second aperture. In some examples, the method at (b) may further comprise (iii) stabilizing a beam energy and an energy spread of the portion of the beam using the second aperture.

The method may comprise sampling a portion of the particle beam 720. In some examples, the portion of the particle beam may be sampled from a central portion. In some example, the portion of the particle beam may be sampled from a non-central portion of the particle beam. In some examples, the portion of the particle beam may comprise a centroid energy. In some examples, the first aperture may select a centroid energy of the particle beam, wherein the centroid energy is equal to the virtual source energy. In some examples, the first aperture position may adjust the selected centroid energy, wherein the first aperture position may control the virtual source energy.

The position of the first aperture may select a centroid energy of the particle beam forming a portion of the particle beam. In some examples, the centroid energy may form the portion of the particle beam. In some examples, the centroid energy may be greater than about 1 MeV. In some examples, the centroid energy may be greater than about 5 MeV. In some examples, the centroid energy may be greater than about 10 MeV. In some examples, the centroid energy may be greater than about 15 MeV. In some examples, the centroid energy may be greater than about 20 MeV. In some examples, the centroid energy may be greater than about 25 MeV. In some examples, the centroid energy may be greater than about 50 MeV. In some examples, the centroid energy may be greater than about 100 MeV. In some examples, the centroid energy may be greater than about 150 MeV. In some examples, the centroid energy may be greater than about 200 MeV. In some examples, the centroid energy may be greater than about 250 MeV. In some examples, the centroid energy may be greater than about 500 MeV. In some examples, the centroid energy may be greater than about 1000 MeV, or 1 GeV. In some examples, the centroid energy may be greater than about 5 GeV. In some examples, the centroid energy may be greater than about 10 GeV. In some examples, the centroid energy may be greater than about 20 GeV. In some examples, the centroid energy may be from about 5 MeV to about 50 GeV. In some examples, the centroid energy may be from about 5 MeV to about 25 MeV. In some examples, the centroid energy may be from about 25 MeV to about 50 MeV. In some examples, the centroid energy may be from about 50 MeV to about 100 MeV. In some examples, the centroid energy may be from about 100 MeV to about 250 MeV. In some examples, the centroid energy may be from about 250 MeV to about 500 MeV. In some examples, the centroid energy may be from about 500 MeV to about 1000 MeV. In some examples, the centroid energy may be from about 1 GeV to about 10 GeV. In some examples, the centroid energy may be from about 10 GeV to about 50 GeV. In some examples, the centroid energy may be greater than about 1000 MeV.

The first aperture may be adjusted (e.g., adjust longitudinal position, adjust transverse position, adjust cross-sectional area). In some examples, the first aperture cross sectional area may be enlarged. In some examples, the first aperture cross sectional area may be enlarged, resulting in an alteration of the energy spread. In some examples, the first aperture cross sectional area may be enlarged, resulting in an increase in the energy spread. In some examples, the first aperture cross sectional area may be shrunk. In some examples, the first aperture cross sectional area may be shrunk, resulting in an alteration of the energy spread. In some examples, the first aperture cross sectional area may be shrunk, resulting in a decrease in the energy spread.

The method may comprise demagnifying the portions of the particle beam from the virtual source with a telescopic subsystem 730.

The method may comprise reducing the energy spread of the portion of the particle beam 740. In some examples, the energy spread reduction may be to about ±0.1 MeV to about ±50 MeV, which may include about ±0.1 MeV to about ±5 MeV, about ±5 MeV to about ±10 MeV, about ±10 MeV to about ±15 MeV, about ±15 MeV to about ±20 MeV, about ±20 MeV to about ±25 MeV, about ±25 MeV to about ±30 MeV, about ±30 MeV to about ±35 MeV, about ±35 MeV to about ±40 MeV, about ±40 MeV to about ±45 MeV, or about ±45 MeV to about ±50 MeV. In some examples, the energy spread may be reduced to about ±1 MeV, about ±5 MeV. In some examples, the energy spread may be reduced to about ±10 MeV, about ±15 MeV, about ±20 MeV, about ±25 MeV, about ±30 MeV, about ±35 MeV, about ±40 MeV, about ±45 MeV, or about ±50 MeV.

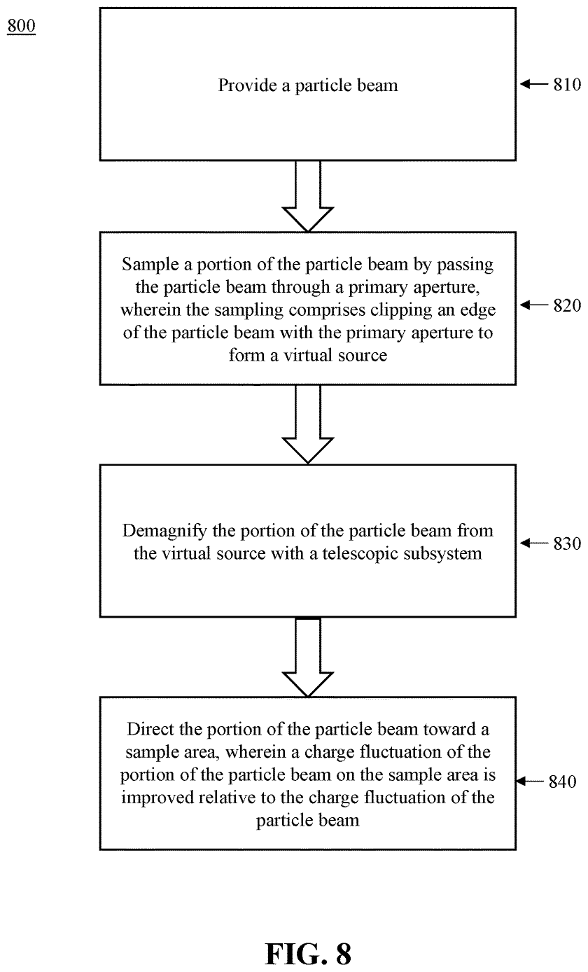

Also disclosed herein are methods 800 for stabilizing a particle beam, such as that in FIG. 8. In some examples, the method may comprise (a) providing a particle beam 810; (b) sampling a portion of the particle beam by passing the particle beam through a first aperture, wherein the sampling comprises clipping an edge of the particle beam with the first aperture to form a virtual source 820; (c) demagnifying the portion of the particle beam from the virtual source with a telescopic subsystem 830; and (d) directing the portion of the particle beam toward a sample area, wherein a charge fluctuation of the portion of the particle beam on the sample area is improved relative to the charge fluctuation of the original particle beam 840.

The particle beam in (a) 810 may have an energy. In some examples, the particle beam in (a) may be high energy. In some cases, the high energy electron beam may have an energy greater than about 1 MeV, greater than about 5 MeV, greater than about 10 MeV, greater than about 50 MeV, greater than about 100 MeV, greater than about 150 MeV, greater than about 200 MeV, greater than about 250 MeV, greater than about 500 MeV, greater than about 1000 MeV, greater than 5 GeV, greater than 10 GeV, greater than 50 GeV, greater than 100 GeV. In some cases, the energy may be from about 1 MeV to about 1000 MeV, from about 1 MeV to about 50 MeV, from about 50 MeV to about 100 MeV, from about 100 MeV to about 150 MeV, from about 150 MeV to about 200 MeV, from about 200 MeV to about 250 MeV, from about 250 MeV to about 500 MeV, from about 500 MeV to about 750 MeV, from about 750 MeV to about 1000 MeV, from about 1000 MeV to about 10 GeV, or from about 10 GeV to about 100 GeV. In some examples, the energy may be greater than about 1 GeV.

The particle beam in (a) 810 may have an energy. In some examples, the particle beam may have a minimum energy. In some cases, the minimum energy may be greater than about 50 MeV, greater than about 100 MeV, greater than about 150 MeV, greater than about 200 MeV, greater than about 250 MeV, greater than about 500 MeV, greater than about 1000 MeV, or greater than about 1000 MeV.

The particle beam in (a) 810 may be generated from a particle beam source. In some examples, the particle beam source may be located along an axis of propagation. In some examples, the particle beam source may be located along a second axis different from the axis of propagation. In some examples, the particle beam source may be cathode-ray tubes. In some examples, the particle beam source may be an electron gun. In some examples, the particle beam source may be an ion source. In some examples, the particle beam source may be a photocathode. In some examples, the particle beam source may be a thermionic source. In some examples, the particle beam source may be an accelerator system. In some examples, the particle beam source may be a particle accelerator. In some examples, the particle beam source may be a plasma accelerator. In some examples, the particle beam source may be a wakefield accelerator system. In some examples, the wakefield accelerator system may be driven by a laser. In some examples, the wakefield accelerator system may be driven by a particle beam. In some examples, the particle beam source may be a radiofrequency accelerator.

The method at (b) 820 may further comprise additional operations. In some examples, the method at (b) may further comprise (i) stabilizing a transverse beam jitter using the first aperture. In some examples, the method at (b) may further comprise (ii) forming the virtual source of the stabilized portion of the beam using a second aperture. In some examples, the method at (b) may further comprise (iii) stabilizing a beam energy and an energy spread of the portion of the beam using the second aperture.

The particle beam may have a charge. In some examples, the particle beam may have a uniform charge throughout the beam. In some examples, the particle beam may have a non-uniform charge throughout the beam. In some examples, the cross section of the particle beam may have a uniform charge. In some examples, the cross section of the particle beam may have a non-uniform charge. In some examples, the center of the particle beam may have a charge uniform to the outer edge of the particle beam. In some examples, the center of the particle beam may have a charge non-uniform to the outer edge, or outer regions, of the particle beam.

The particle beam may have a charge fluctuation. In some examples, the particle beam may have a uniform charge fluctuation. In some examples, the particle beam may have a non-uniform charge fluctuation. In some examples, the center of the particle beam may have a charge fluctuation. In some examples, the outer edge of the particle beam may have a charge fluctuation. In some examples, the outer edge of the particle beam and the center of the particle beam may have equal charge fluctuation. In some examples, the outer edge of the particle beam and the center of the particle beam may have an unequal charge fluctuation. In some examples, the outer edge of the particle beam charge fluctuation may be larger than the center of the particle beam charge fluctuation. In some examples, the outer edge of the particle beam charge fluctuation may be smaller than the center of the particle beam charge fluctuation.

The first aperture may be adjusted. In some examples, the first aperture longitudinal position may be adjusted. In some examples, the first aperture transverse position may be adjusted. In some examples, the first aperture cross sectional area may be adjusted. In some examples, the first aperture cross sectional area may be enlarged. In some examples, the first aperture cross sectional area may be enlarged, resulting in an alteration of the charge fluctuation. In some examples, the first aperture cross sectional area may be enlarged, resulting in an increase in the charge fluctuation. In some examples, the first aperture cross sectional area may be shrunk. In some examples, the first aperture cross sectional area may be shrunk, resulting in an alteration of the charge fluctuation. In some examples, the first aperture cross sectional area may be shrunk, resulting in a decrease in the charge fluctuation.

The method may comprise demagnifying the portions of the particle beam from the virtual source with a telescopic subsystem 830.

The method may adjust the particle beam charge fluctuation 840. In some examples, the method may increase the particle beam charge fluctuation. In some examples, the method may decrease the particle beam charge fluctuation. In some examples, the method may decrease the particle beam charge fluctuation relative to the provided particle beam. In some examples, the method may relatively decrease the charge fluctuation. In some examples, the relative charge fluctuation decrease may be from about 30% to about 90%. In some examples, the relative charge fluctuation decrease may be from about 30% to about 40%. In some examples, the relative charge fluctuation decrease may be from about 40% to about 50%. In some examples, the relative charge fluctuation decrease may be from about 50% to about 60%. In some examples, the relative charge fluctuation decrease may be from about 60% to about 70%. In some examples, the relative charge fluctuation decrease may be from about 70% to about 80%. In some examples, the relative charge fluctuation decrease may be from about 80% to about 90%. In some examples, the relative charge fluctuation decrease may be about 30%. In some examples, the relative charge fluctuation decrease may be about 40%. In some examples, the relative charge fluctuation decrease may be about 50%. In some examples, the relative charge fluctuation decrease may be about 60%. In some examples, the relative charge fluctuation decrease may be about 70%. In some examples, the relative charge fluctuation decrease may be about 80%. In some examples, the relative charge fluctuation decrease may be about 90%. In some examples, the relative charge fluctuation decrease may be greater than about 30%. In some examples, the relative charge fluctuation decrease may be greater than about 40%. In some examples, the relative charge fluctuation decrease may be greater than about 50%. In some examples, the relative charge fluctuation decrease may be greater than about 60%. In some examples, the relative charge fluctuation decrease may be greater than about 70%. In some examples, the relative charge fluctuation decrease may be greater than about 80%. In some examples, the relative charge fluctuation decrease may be greater than about 90%.

While embodiments of the present disclosure have been shown and described herein, it will be obvious to those skilled in the art that such embodiments are provided by way of example only. Numerous variations, changes, and substitutions will now occur to those skilled in the art without departing from the disclosure. It may be understood that various alternatives to the embodiments of the present disclosure may be employed in practicing the present disclosure. It is intended that the following claims define the scope of the present disclosure and that methods and structures within the scope of these claims and their equivalents be covered thereby.

What is claimed is:

1. A system comprising:
a source of a particle beam configured to generate the particle beam;
an aperture positioned on an axis of propagation of the particle beam, wherein the aperture is configured to form a virtual source comprising a sample of the particle beam; and
a telescopic subsystem configured to receive the sample of the particle beam from the virtual source and image the sample of the particle beam onto a sample area, wherein, at the sample area, at least one property of the sample of the particle beam is more stable than the corresponding property of the particle beam at the source of the particle beam.

2. The system of claim 1, wherein the at least one property of the sample of the particle beam comprises a centroid energy, a pointing stability, a beam energy spread, a beam divergence, a beam emittance, or a particle beam location.

3. The system of claim 1, wherein an energy of the particle beam is at least 4 megaelectron Volts (MeV).

4. The system of claim 3, wherein the energy of the particle beam is greater than 100 MeV.

5. The system of claim 1, further comprising an additional aperture positioned along the axis of propagation upstream of the aperture, wherein the additional aperture is defined by an opening in a reflective surface positioned along the axis of propagation.

6. The system of claim 1, wherein the particle beam is an electron beam.

7. The system of claim 1, wherein the particle beam before the aperture comprises a beam jitter characterized by (i) a deviation in angle of greater than 0.1 milliradian or (ii) an offset of greater than 0.1 millimeter.

8. The system of claim 1, wherein the source of the particle beam comprises a wakefield accelerator system or a radiofrequency accelerator.

9. The system of claim 8, wherein the wakefield accelerator system is driven by a laser or the particle beam.

10. The system of claim 1, wherein the aperture is configured to limit an emittance of the particle beam, thereby limiting a transverse pointing error, a beam divergence, and a beam size, to form the sample of the particle beam.

11. The system of claim 1, wherein the aperture is configured to select a centroid energy and an energy range of the particle beam to form the sample of the particle beam.

12. The system of claim 1, wherein the aperture defines a source point of the virtual source comprising the sample of the particle beam.

13. The system of claim 1, wherein the aperture is fixed or adjustable along the axis of propagation.

14. The system of claim 1, wherein an energy of the virtual source is controlled by the location of the aperture, wherein the energy comprises centroid or mean particle energy.

15. The system of claim 2, wherein the sample of the particle beam comprises an energy spread around the centroid energy of the particle beam from the virtual source of less than about 10% of the centroid energy.

16. The system of claim 1, wherein the telescopic subsystem is configured to perform a variable transverse demagnification from the virtual source to the sample area.

17. The system of claim 1, wherein the telescopic subsystem is tunable.

18. The system of claim 1, wherein the telescopic subsystem further comprises two or more magnetic quadrupoles or one or more magnetic solenoids.

19. The system of claim 1, wherein the sample of the particle beam is an electron bunch with a charge from 1 attocoulomb to 100 femtocoulomb.

20. The system of claim 1, wherein the sample area comprises a single event effect testing sample.
